(19) United States
(12) Patent Application Publication
(10) Pub. No.: US 2026/0370231 A1
(43) Pub. Date: Nov. 19, 2026

(54) DUAL-CORE MULTI-MODE LC VOLTAGE-CONTROLLED OSCILLATOR WITH A WIDE TUNING RANGE

(71) Applicant: Microchip Technology Incorporated, Chandler, AZ (US)

(72) Inventors: Hormoz Djahanshahi, Port Moody (CA); Siddhartha Hazra, Durgapur (IN); Amir Hossein Masnadi Shirazi Nejad, North Vancouver (CA)

(73) Assignee: Microchip Technology Incorporated, Chandler, AZ (US)

(21) Appl. No.: 19/301,817

(22) Filed: Aug. 15, 2025

(30) Foreign Application Priority Data
May 15, 2025 (IN) 202511046878

(51) Int. Cl. H03L 7/099; H03B 5/12

(52) U.S. Cl. CPC H03L 7/099; H03B 5/1228; H03L 2207/06

(57) ABSTRACT

A circuit for a clock synthesizer phase-locked loop (PLL) includes a voltage-controlled oscillator (VCO). The VCO includes two cores (or inductors). The cores may have a folded layout configuration, with the two sets of terminals of the inductors near each other. The relative phase of the alternating currents in the inductors can be controlled in different modes to be in phase or out of phase, which affects the mutual inductance between the inductors and the resulting frequency of the VCO. The different modes allow for a wider overall frequency tuning range for the VCO. In some examples, the outputs of the two cores can be combined using a multiplexer (or sets of switches), reducing the phase noise of the output signal.

### CROSS-REFERENCE TO RELATED APPLICATION

The present application claims the benefit of U.S. provisional patent application no. U.S. 63/325,178 filed on 30 Mar. 2022, entitled “SYSTEM AND METHOD FOR SELECTING RESIDENTIAL PREMISES FOR TEMPORARY RENT,” and U.S. patent application Ser. No. 18/115,042 filed on Feb. 28, 2023, entitled “SYSTEM AND METHOD FOR DETERMINING OPTIMAL PLACEMENT STRATEGY FOR RENTAL ACCOMMODATIONS,” and U.S. patent application Ser. No. 18/818,046 filed on Aug. 28, 2024, entitled “SYSTEM AND METHOD FOR DETERMINING OPTIMAL PLACEMENT STRATEGY AND BOOKING ACCOMMODATIONS,” the contents of which are hereby incorporated by reference.

### BACKGROUND

### A. Technical Field

The present disclosure generally relates to booking accommodations for users, for example, visitors. More specifically, the present disclosure relates to a computer-implemented system and method for enabling the visitor to find optimal accommodation in terms of customer satisfaction, and for the host to maximize profit.

### B. Description of Related Art

Determining a placement strategy and booking accommodation is a typical step for visitors. Generally, the visitors research for accommodations with respect to the point of interest, or location of interest planned for visit. In addition, criteria such as availability, affordability, dining options, pet care and other criteria need to align with the determined accommodation.

Websites and applications such as Airbnb, VRBO, or Booking.com are some online services that facilitates the visitor to book accommodations. The visitor could browse through a number of accommodations near their point of interest and book accommodations. Further, the service facilitates the visitor to filter accommodation based on criteria such as accommodation date and location. Furthermore, the service facilitates the visitor to filter accommodation based on criteria such as amenities. Thereby, these services enable the visitor to search at least one location proximal to the point of interest, remotely and book accommodations.

As the consumer base continues to expand, their demand and preference also expand. In attempting to address the needs of visitors, it is important to maintain a minimal level of complexity for a given accommodation system. At the same time, effective management of the system by the owners is equally taken into consideration. One of the common accommodation problems is that the owners may have an extremely fragmented schedule for the utilization of premises. This fragmentation leads to the fact that at some time, very often some premises are not occupied. If the premises are empty, this leads to loss for the owners. Since the existent systems can only place the dates of residence in individual units and cannot schedule the transfer between units, they cannot fill in the empty premises and this results in the loss for owners and limiting options for visitors. Since the existing services do not calculate a monetary estimation for different options, visitors could miss optimally suited accommodations.

In addition, customers are only able to indicate their preference for amenities in a simple Yes (mandatory)/No form. For example, having a washing machine is certainly a plus, but it may not be absolutely necessary, as a customer can go to a laundry for washing, spending extra time and money on it. Existing systems do not allow specifying requirements to filters that are useful but not absolutely necessary.

In light of the above-mentioned problems, there is a need for a computer-implemented system and method for determining optimal placement strategy and booking accommodations taking into account.

### SUMMARY

The present disclosure discloses a system for determining optimal placement strategy and booking accommodations. The system comprises a visitor device associated with a visitor, and a server comprising a database and a computing device in communication with the database. The server is in communication with the visitor device. The database is configured to store information related to a plurality of lodging units and the visitors. The computing device comprises a memory unit storing a set of modules and a processor configured to executed the modules. The set of modules comprises an input module, an analysis module, a booking module and a payment module.

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

The input module is configured to receive a request data for placement strategy from the visitor. The request data comprises check-in date, check-out date, a location of interests and optionally criteria (filters) for amenities. Criteria for amenities can be expressed either as mandatory requirements (must have) or as a monetary criterial value that is the penalty that a visitor imposes on a home for not having this particular amenity. In addition, the request data can have monetary criterial values for penalties that a customer imposes for moving during the total reservation either internally within the same location, i.e., a house (internal move penalty) or externally (external move penalty) to other location during the reservation. Moreover, a criterial monetary value can be assigned to a commute distance or time of an accommodation to the visitor's point of interest, that is a penalty that the visitor imposes for the commute to the point of interest.

The analysis module is configured to determine one or more placement strategy based on the request data. Each placement strategy comprises one or more lodging units connected by either external or internal moves.

Optimization in the system is achieved through a combination of search methodologies and dynamic programming. Depending on specific requirements, either breadth-first search or the use of a large language model (LLM) may be utilized to conduct the initial search process. Subsequently, an extended dynamic programming algorithm can optimize the results by identifying multiple placement strategies, thereby offering a variety of choices to the visitor. Each workflow node is uniquely defined by a combination of a rental unit and a date. The system computes a target function for each node and the selected placement strategies, incorporating criterial values derived from aggregated room prices, moves, and amenities. This facilitates a comprehensive optimization of choices.

By the end of calculation, the system presents variety of placement strategies that satisfies the customer date range. Each strategy comprises date of check-in and check-out of every lodging unit included into the placement. The placement strategies are sorted by the strategy criteria values, i.e., a score to represent an optimal level of the strategy. At the same time every placement strategy presents the monetary value, i.e., the price the customer needs to pay for accommodation.

The booking module is configured to enable the visitor to review one or more placement strategies and select one placement strategy. In case of internal moves the system optionally creates the reservation that unites reservations inside one address connected by internal moves to one reservation on the property, i.e., a parent property for saving booking fees. That means if a placement strategy contains internal movement between one lodging unit and another lodging unit, the system unites a reservation for all lodging units using a parent property. The payment module is configured to enable visitor to pay for the chosen lodging. The payment is sent to the management firm that forwards part of the payment to a host.

Advantageously, the present disclosure's system and method assists in determining the optimal accommodation rental unit or rental units for the visitor's lodging based on the visitor requirements, such as the start and end dates, point of interest, and criterial values for amenities. It allows a visitor to select both a single-unit and multiunit placement strategy. In addition, it introduces the parent unit feature, which allows for the system to create one single booking for strategies with internal moves, this way it saves the expenses for extra reservation, such as the fixed fee from customer's transaction fee, thus reducing the total amount of the booking. The algorithm and computer-implemented system and method allows the visitor to view multiple placement strategies and choose the most suitable plan. Furthermore, the technology assures high occupancy rate of premises filling the gaps in a fragmented premises schedule. The method is incorporated in the system comprising the server and the visitor device in communication with the server. The server comprises at least one computing device and at least one database for storing information related to the lodging unit and the visitors. The computing device comprises the memory unit storing a set of modules and the processor configured to executed the modules. The modules comprise the input module, the analysis module, the booking module and the payment module.

At one step, the input module receives a request data for placement strategy from the visitor. The request data comprises check-in date, check-out date, location of interest. The request data, optionally, comprises criteria for selected amenities, either expressed as Mandatory Yes/Required, or as a monetary penalty for not having this amenity, monetary value for lodging unit, monetary criterial value (penalty) for commute from the lodging unit to the location of interest, monetary criterial value for moving from one lodging unit to another lodging unit within one address (internal move) and monetary criterial value for moving from one lodging unit to another lodging unit with the different address (external move).

At another step, the analysis module determines one or more placement strategies based on the request data. Each placement strategy comprises one or more lodging units. The placement strategy further comprises date and time of check-in and check-out of each lodging unit. Each placement strategy further comprises a score (a criterial value that takes into account aggregated room price, monetary criterial value for moves and amenities) to represent an optimal level of the placement strategy, the score value enables the visitor to select optimal placement strategy.

At yet another step, the booking module enables the visitor to review one or more placement strategies and select one placement strategy. If the visitor selects movement between the one lodging unit and another lodging unit within one address, the system unites reservations of these units. At yet another step, the payment module enables the visitor to make payment for the selected lodging unit. The payment is sent to the management firm that forwards part of the payment to a host.

Other objects, characteristics, and benefits of the present disclosure will become clear from the thorough explanation that follows. However, the detailed description and specific examples, while indicating specific embodiments of the disclosure, are provided solely for illustration purposes, as various changes and modifications within the spirit and scope of the disclosure will be apparent to those skilled in the art from this detailed description.

### BRIEF DESCRIPTION OF DRAWINGS

The foregoing summary, as well as the entire description of the disclosure that follows, are more easily understood when read in combination with the associated drawings. Exemplary structures of the disclosure are given in the pictures to illustrate the disclosure. The disclosure, however, is not limited to the precise techniques and structures described herein. The description of a method step or structure denoted by a number in a picture is applicable to the description of that method step or structure denoted by that same numeral in any subsequent drawing herein.

FIG. 1 exemplarily illustrates an environment for determining optimal placement strategy and booking accommodations, according to an embodiment of the present disclosure.

FIG. 2 exemplarily illustrates an architecture of the environment of FIG. 1 for determining optimal placement strategy and booking accommodations, according to an embodiment of the present disclosure.

FIG. 3 exemplarily illustrates a block diagram of an accommodation management server, according to an embodiment of the present disclosure.

FIG. 4 shows an analysis table before finding a path using an algorithm, according to an embodiment of the present disclosure.

FIG. 5 shows two analysis tables after finding the path using the algorithm, each analysis table represents a placement strategy that is found according to an embodiment of the present disclosure.

FIG. 6 exemplarily illustrates a flowchart of a method for determining optimal placement strategy and booking accommodation, according to an embodiment of the present disclosure.

FIG. 7 shows a screenshot of a user interface for specifying amenities needed and optionally setting a criterial value for an Amenity by the visitor, according to an embodiment of the present disclosure.

FIG. 8 shows a screenshot of a user interface for optionally giving monetary value for internal move, external move and distance or time from the accommodation to the point of interest.

FIG. 9 shows a screenshot of different placement strategy specified by a score value, according to an embodiment of the present disclosure.

FIG. 10 shows a screenshot of a user interface of the visitor reservation that unites reservations inside one address connected by internal moves to one reservation on the property, or lodging unit, according to an embodiment of the present disclosure.

FIG. 11 shows an analysis table before finding a path using an algorithm, according to an embodiment of the present disclosure.

FIG. 12 exemplarily illustrates a flowchart of a method for building an index of multiunit planning.

FIG. 13 exemplarily illustrates a flowchart of a method for searching an index of multiunit planning.

FIG. 14 exemplarily illustrates a one-dimensional range tree.

FIG. 15 exemplarily illustrates a flowchart of a method for LLM-based accommodation planning.

FIG. 16 exemplarily illustrates a flowchart of a method for deep relational learning-based constraint satisfaction problem for accommodation planning.

FIG. 17 exemplarily illustrates a flowchart of a method for fuzzy pattern matching for fulfilling accommodation requests.

FIG. 18 exemplarily illustrates a flowchart of a method for using a breadth first search.

### DESCRIPTION OF EMBODIMENTS IN DETAIL

A description of embodiments of the present disclosure will now be given with reference to the Figures. It is expected that the present disclosure may be embodied in other specific forms without departing from its spirit or essential characteristics. The described embodiments are to be considered in all respects only as illustrative and not restrictive.

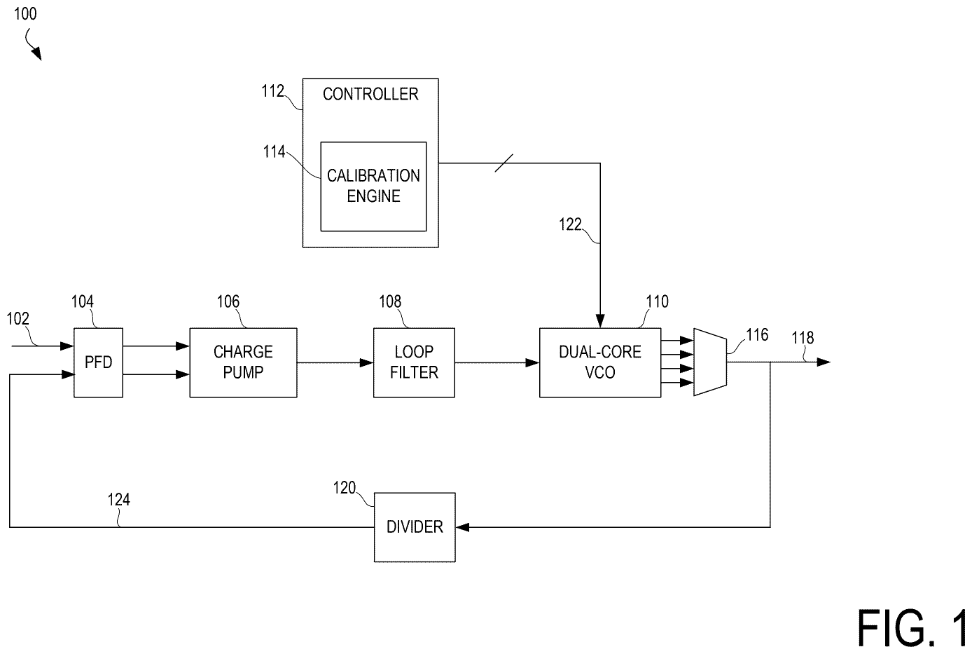

FIG. 1 exemplarily illustrates an environment 100 of a system for determining optimal placement strategy and booking accommodation, according to an embodiment of the present disclosure. The system is configured to provide at least one optimal placement strategy to the visitor. The system is further configured to facilitate the visitor to book an optimal accommodation using the optimal placement strategy. The system is configured to provide criterial value and monetary price of the placement strategy. The placement strategy comprises the sequence of lodging units and the information about movement dates between the lodging units.

The system comprises an accommodation management server 102, and a visitor device 104. The accommodation management server 102 is configured to provide service for determining optimal placement strategy and booking accommodation. The visitor device 104 is associated with the visitor. The visitor device 104 is in communication with the server 102 via a network 106. The visitor device 104 is a computing device configured to provide access to the service provided by the accommodation management server 102. The accommodation management server 102 is also referred as server 102.

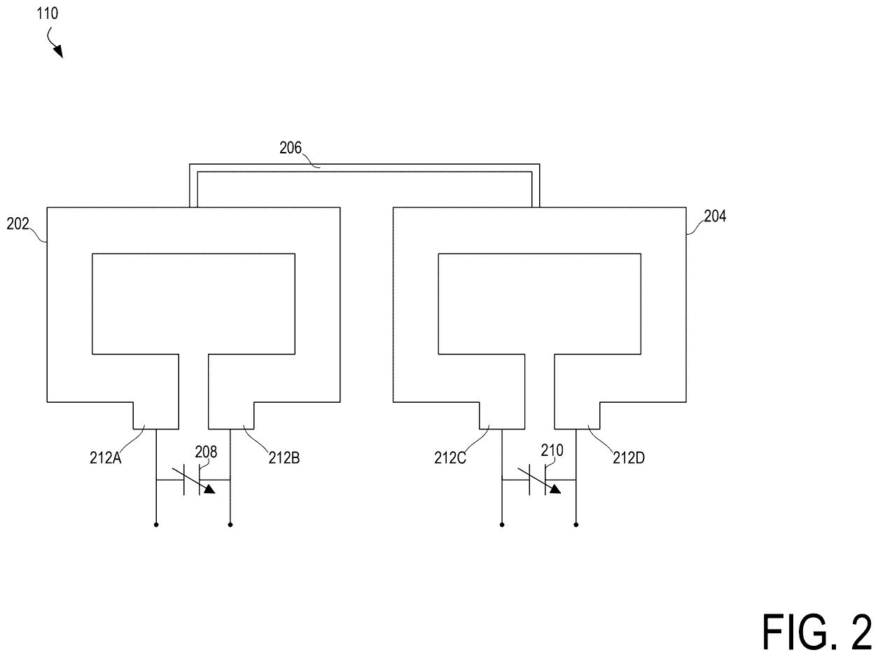

FIG. 2 exemplarily illustrates an architecture 200 of the environment 100 of FIG. 1 for determining optimal placement strategy and booking accommodations, according to an embodiment of the present disclosure. The system is executed in a computing environment. In one embodiment, the computing environment is a cloud computing environment, for example, AWS cloud 202. The system comprises the accommodation management server 102. In one embodiment, the server 102 is at least one of a general or special purpose computer. In an embodiment, the server 102 operates as a single computer, which can be a hardware and/or software server, a workstation, a desktop, a laptop, a mainframe, a supercomputer, a server farm, cloud hosting and so forth. In an embodiment, the computer could be touchscreen and/or non-touchscreen device and could run on any type of OS, such as iOS™, Windows™, Unix™, Linux™ and/or others. In an embodiment, the computer is in communication with network 106. Such communication can be via a software application, a mobile app, a browser, an OS, and/or any combination thereof. The accommodation management server 102 comprises a computing device 108 and at least one database 110.

In one embodiment, the computing device 108 may be one or more EC2 instances 206 which are provisioned and running in Private Subnets 224, which are secure and isolated from the internet. In one example, a software application is executed on an EC2 instance 206, it interacts with a S3 bucket (Rent Optimum Bucket) 208 where artifacts for property images, visitor documents, etc., are stored and accessible by the application. The application running in the EC2 instances 206 establishes the connection with Amazon RDS 226 for MySQL database instance 110 running in the Private Subnet (Database Subnet) 228 and only allows connection request from the EC2 instances. For increased performance and high availability, VPC subnets (214, 216) span across two Availability Zones (AZs), which run the workload. Database instance stores and manages the information about properties' availability, customer reviews, etc.

The visitor device 104 have the capability to provide the visitor an interface to interact with the services provided by the server 102. The interface, for example, a mobile application that allows the device 104 to wirelessly connect with the server 102 via the network 106. The visitor device 104 connects with the server 102 via internet/local network. The visitor device 104 may be, for example, a desktop computer, a laptop computer, a mobile phone, a personal digital assistant, and the like.

For increased security and performance, the visitor device 104 is configured to connect to the application running in the virtual private cloud (VPC) 210 through Cloudflare® 212 service. From Cloudflare® 212, the requests are redirected to the amazon cloud 202 through internet gateway (IG) 218 and are sent to application load balancer (ALB) 220 in the public subnet 222. The ALB 220 directs the requests to EC2 instances 206 running in the two availability zones (AZs) (214, 216) for the application's high availability and sends a response. The EC2 instances 206 are provisioned and running in private subnets 224, which are secure and isolated from the internet.

The application running in the EC2 instances 206 establishes the connection with amazon relational database service (Amazon RDS) for MySQL database instance 226 running in a private subnet, for example, database subnet 228, and only allows to accept a connection request from the EC2 instances 206. The database instance 226 stores and manages the information about properties' availability, customer reviews, etc. Artifacts for property images, visitor documents, etc., are stored and accessible from S3 bucket 208, which could be accessed by the application running in the EC2 instances 206. The standard search is performed on the server 102 and the advanced multi-unit search is performed by AWS Lambda Function 230.

The server 102 makes an HTTP request 230 to the Lambda function 230 providing the visitor's search data. The lambda function 230 analyses data and solves the complex algorithm for finding the optimal lodging for the visitor in case of internal and external moves. When the server 102 creates all possible accommodations, a response is sent to the visitor's device 104 through Cloudflare® 212. For monitoring and logging, the system includes a monitoring service. The monitoring service, for example, Amazon® CloudWatch is configured for EC2 instances 206 and RDS to check critical information like system utilization, performance, errors, etc. The monitoring service includes CloudWatch metrics 234 and CloudWatch logs 236, which contains infrastructure metrics and application logs metrics of the infrastructure for monitoring and alerting. The system further includes system manager 238 for system management and VPC flow logs 240 to capture information related to the network flows sent from and received by the VPC 210.

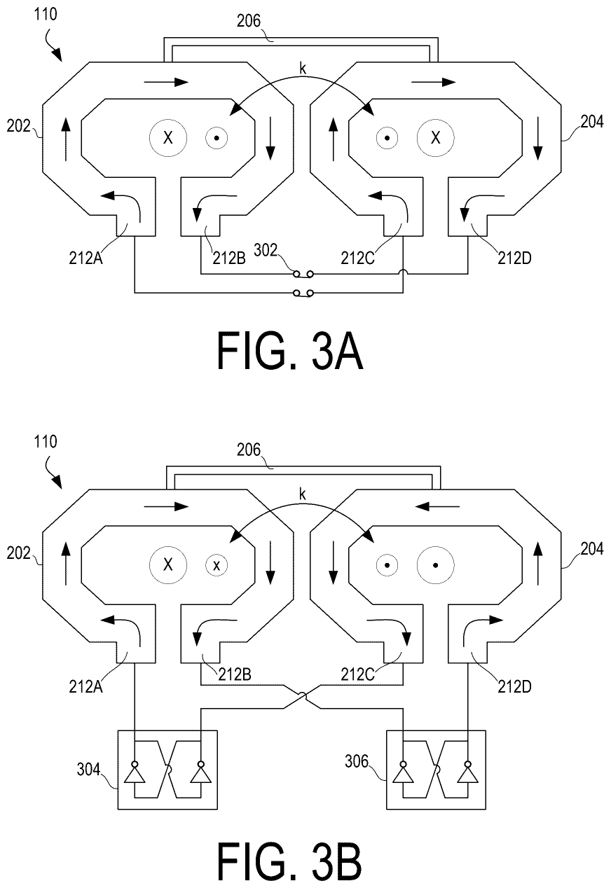

FIG. 3 exemplarily illustrates a block diagram 300 showing the components and connection between the components of the server 102, according to an embodiment of the present disclosure. The server 102 comprises the computing device 108 and at least one database 110. The computing device 108 comprises the processor 304 and the memory 306. The memory 306 stores a set of program modules executable by the processor 304. The set of modules includes an input module 308, an analysis module 310, a booking module 312 and a payment module 314. The input module 308 is configured to receive a request data for placement strategy from the visitor. The request data comprises check-in date, check-out date, a location of interest and optionally criteria (filters) for amenities. Criteria for amenities can be expressed either as mandatory requirements (must have) or as a monetary criterial value that is the penalty that a visitor imposes on a home for not having this particular amenity. The location of interest refers to the location that the visitor planned to visit. The request data, optionally, comprises a criterial value of each amenity, monetary value for lodging unit, criterial value to commute from the lodging unit to the location of interest, criterial value for moving from one lodging unit to another lodging unit.

For example, an amenity of the request data may have a value 0 to 100, and the visitor may provide a value 20. In one example, the criterial value represents importance of the criteria. In another example, the criterial value represents a monetary value of this criterion, that is the penalty that a visitor imposes on the lodging unit in the absence of particular amenity. In addition, the request data can have monetary criterial values for penalties that a customer imposes for moving during the total reservation either internally within the same location, i.e., a house (internal move penalty) or externally (external move penalty) to other location during the reservation. Moreover, a criterial monetary value can be assigned to a commute distance or time of an accommodation to the visitor's point of interest, that is a penalty that the visitor imposes for the commute to the point of interest.

The analysis module 310 is configured to determine one or more placement strategies based on the request data. Each placement strategy comprises at least one lodging unit or a sequence of lodging units. Further each placement strategy includes information about moving from one lodging unit to another lodging unit within the found sequence. The system enables the visitor to create reservation that unites reservations inside one address connected by internal moves to one reservation on the property, i.e., a parent property.

Further, each placement strategy comprises a score (criterial value) to represent an optimal level of the placement strategy. The score value is based on the presence or absence of specified filters by increasing the value in the case of absence. The score value enables the visitor to evaluate and identify optimal placement strategy. The booking module 312 is configured to enable the visitor to review one or more placement strategies and select one placement strategy. The payment module 314 is configured to enable the visitor to make payment for the selected lodging strategy. The payment is sent to the management firm that pays to a host.

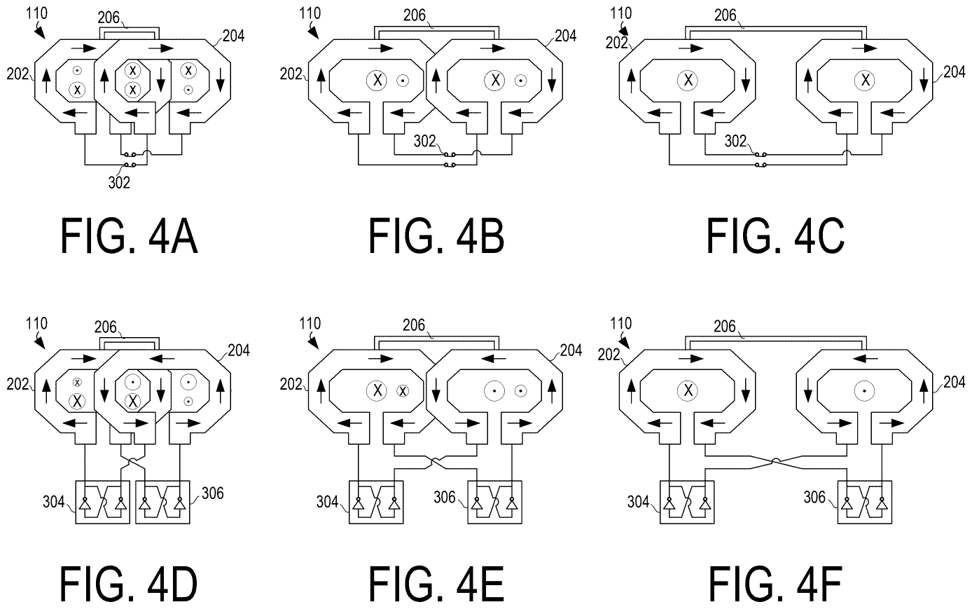

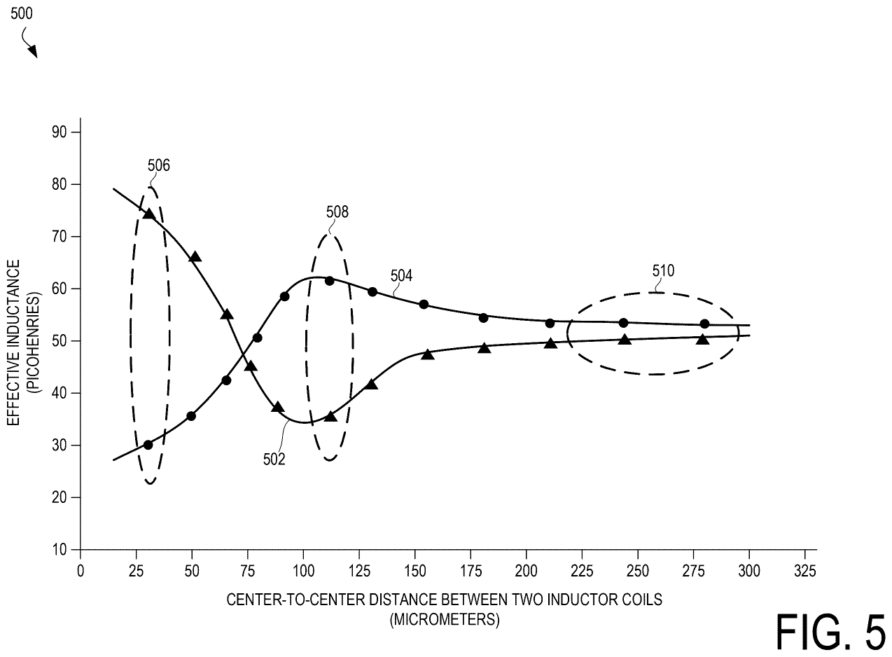

Referring to FIGS. 4-5, analysis tables (400 and 500) are shown before and after determining a path using an algorithm, respectively. In one aspect, the system also comprises an algorithm for determining the best path for the visitors. In one example, the algorithm finds such pathways using Bellman's dynamic programming approach. In one embodiment, the system includes an analysis table for utilizing an algorithm to discover the pathways. In one embodiment, the analysis table includes the visitor's trip dates as well as the units or rooms available in the residential premises, or accommodation. In one embodiment, the table 400 displays the analyses for each specific day in each individual unit in the system prior to determining the path (as shown in FIG. 4). Referring to FIG. 5, the table 500 displays the analyses for each specific day in each individual unit as well as the visitor's transfers between units in the system after determining the path.

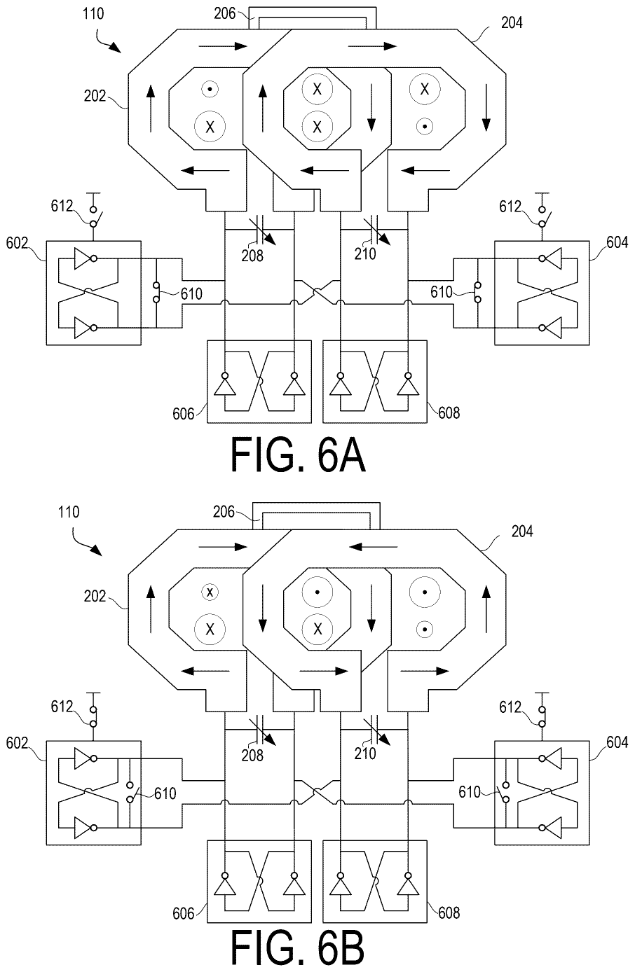

FIG. 6 exemplarily illustrates a flowchart of a method 600 for determining optimal placement strategy and booking accommodation, according to an embodiment of the present disclosure. At step 602, a visitor specifies the start and end dates and location (point of interest) of the trip in the system. Optionally, the visitor specifies the criteria (filters) for amenities needed for a trip, some criteria are specified as mandatory and some criteria are specified as useful but not absolutely necessary giving a monetary criterial value for useful criteria that define a penalty for not having this criteria. Optionally, the visitor gives a criterial monetary value for moving from one unit to another within one location, i.e., internal move inside at the same property. optionally, the visitor gives a criterial monetary value for moving from one location to another i.e., external move. optionally, the visitor indicates the monetary value per unit of distance or time for commute from the accommodation to his point of interest.

In one embodiment, the accommodations include, but not limited to, an apartment, a studio, a room, a bed, and so forth. In one embodiment, the criteria mentioned by the visitor include, but not limited to reviews about the quality of the services provided, availability of a private or shared bathroom (i.e., toilet, dining room, etc.), size of the beds, and/or any other services, such as the presence of the Internet, cable or TV, network, jacuzzi, and so on.

At step 604, the system develops an placement strategy that specifies the dates of residence in each individual unit and the transfers between the units based on the received criteria. As a result of development, the application outputs variety of placement strategies.

At step 606, in case of internal moves, the system optionally creates the reservation that unites reservations inside one address connected by internal moves to one reservation on the property, i.e., a parent property.

At step 608, the system calculates the target function (i.e., the criterial value) for each strategy for each specific day in each room. In the base case, this target function is the sum of the cost of living in each room during travel plus the sum of the costs of moving into a new room, including cleaning the room. In a more complex version, the cost of living per day is adjusted at the price of adjustments for the provision of services to the visitor. The service for the visitor is a convenience (amenity), such as a private bathroom. The convenience also includes the proximity of the premises to a place that is the main purpose of the visitor's trip, for example, a university. The target function for a particular state (defined by a rental unit and date) within a strategy does not change during further analysis in accordance with the Bellman dynamic programming. The main idea of dynamic programming is that at each step the optimal strategy for the next step is calculated.

Following the program's outcomes, the visitor discovers different options at step 610. In one embodiment, each approach is specified by a criterial value. As a consequence of the computation, the visitor in this situation, the one seeking for premises, obtains a certain number of strategies. Each strategy has a price; that is, by looking at the strategy, the visitor may determine the price that must be paid for the plan. In one embodiment, the visitor may choose any of the tactics that he or she believes is the best of the available options. An analogy is when a person is searching for ticket flights from one location to another and sees the different ticket options that differ in prices and number of airport transfers. Moving between dwellings like this will very often helps to find the best placements, or in many cases it can find the only possible placements, because all the possibilities with one room can be occupied.

In one embodiment, the unit daily prices used in the optimization algorithm for a visitor's accommodation can be recalculated based on the visitor input. For example, one type of space (i.e., set by the landlord) such as an apartment, costs $98 per day. This type of space (i.e., an apartment) may include or allow the visitors to use a washing machine, an extra bed, and other amenities. It can also be in short walking distance to the point of interest of the visitor, for example a university where the visitor studies. The visitor may indicate their estimate (for example, through the use of appropriate web forms) to pay an additional $28 for the short walking distance, $5 for the washing machine, and $3 for the extra bed. As a result, the criterial value for the day will be 98−20−5−3=60. Similarly, another apartment can cost $75 but be in a long distance from the university, has an extra bed but does not have a washing machine. Thus, the criterial value will be $75−5=70. Hence, from the visitor perspective, the 1st apartment has more value than the 2nd one despite having the higher nominal price. In one embodiment, the criterial value is used to determine the best possible placement.

At step 612, visitor selects the optimal strategy from among multiple options.

At step 614, the visitor pays for the chosen lodging, and the money is transmitted to the management firm and then to a host. Further, the transaction costs are paid. In one embodiment, the system also determines the best strategy for selecting residential properties, taking into consideration the move from one residential property to another over the course of the trip and adjusting the price to reflect the services offered to the guest. By analogy, such a move from one room to another is similar to a situation when a person flies and does not take a direct plane ticket from one city to another, but makes a transfer.

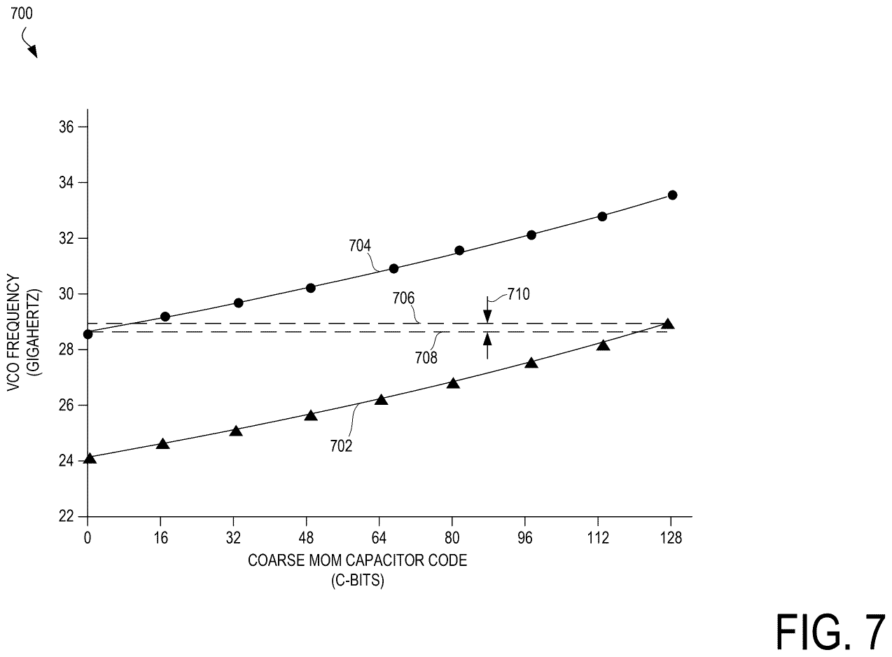

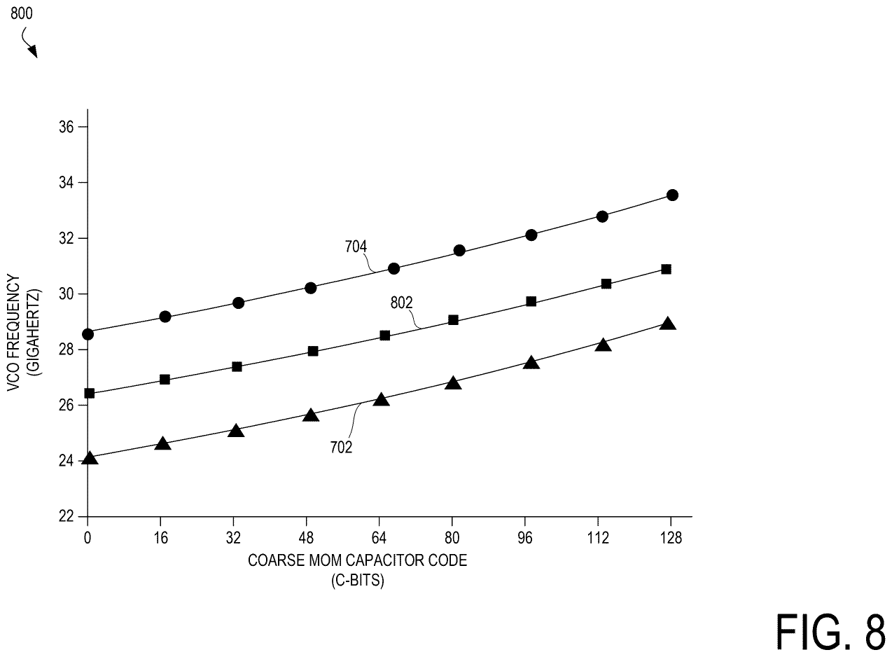

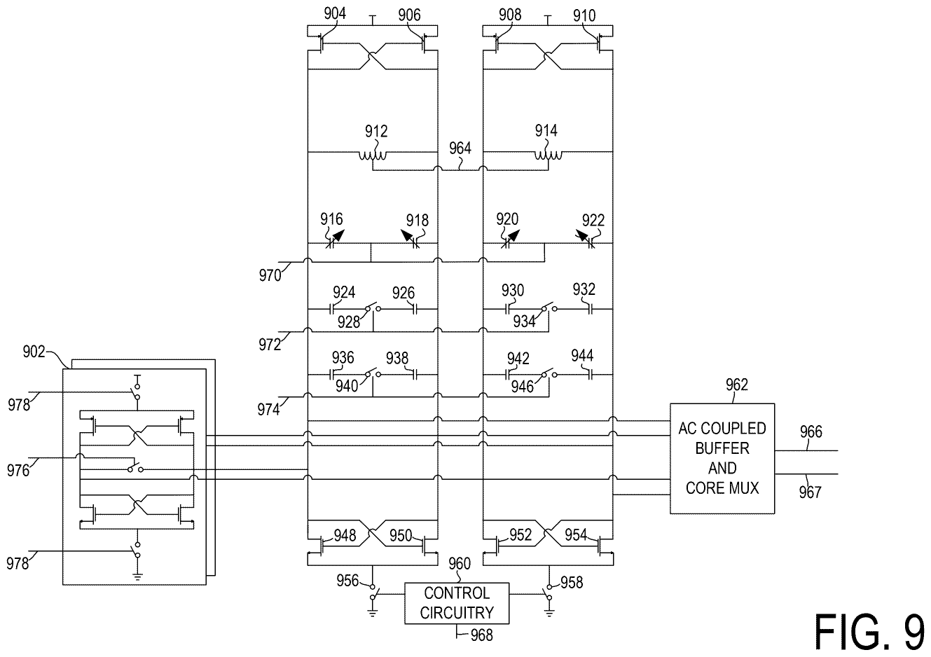

FIG. 7 shows a screenshot 700 of a user interface for specifying amenities needed and optionally setting a criterial value for a useful but not necessary amenity by the visitor, according to an embodiment of the present disclosure. The system uses both Boolean form and monetary form to specify amenities. The criterion value of 0 refers to the mandatory amenities defined by the visitor, and the range of positive values refers to the penalty imposed by the visitor for not having the useful but not necessary amenities. In the current example, the amenities including bed, air conditioner, private bath, table, and Wi-Fi has 0 as the criterial value to indicate mandatory amenity. The amenities including barbeque, pool, tea/coffee have criterial values ranging between 8 to 20 to indicate the penalty imposed by the visitor for not having the amenity. FIG. 8 shows a screenshot 800 of a user interface for optionally giving criterial monetary values for internal move, external move and distance or time for the commute from the accommodation to the point of interest. The system enables the visitor to set a price for being in a distance from a point of interest. The further the distance for the commute from the point of interest, the higher the criterial price. The system further enables the visitor to set a price for an external move. The higher criterial price refers to less willingness of the visitor to move. The system further enables the visitor to set a price for a move inside the same property. The higher criterial price refers to less willingness of the visitor to move. FIG. 9 shows a screenshot 900 of different placement strategy specified by a score value, according to an embodiment of the present disclosure.

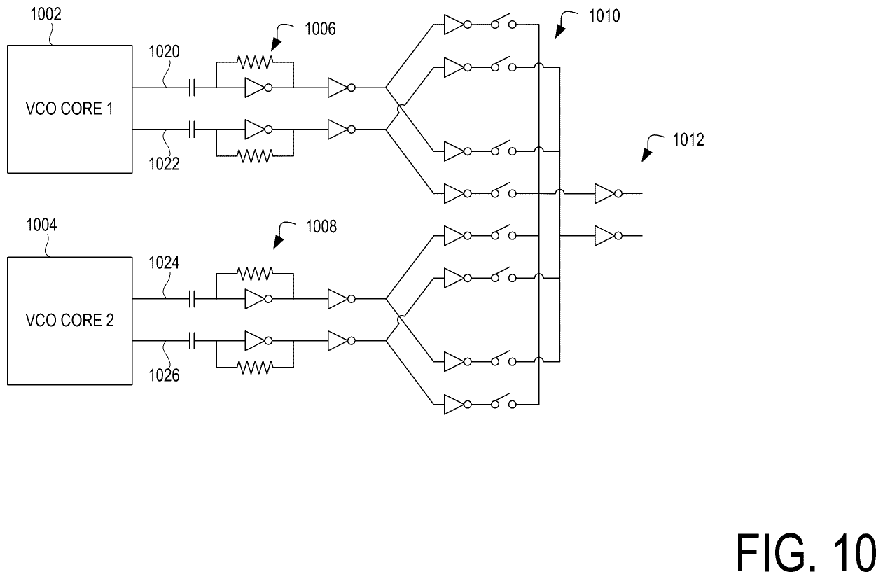

FIG. 10 shows a screenshot 1000 of a user interface of the visitor reservation that unites reservations inside one address connected by internal moves to one reservation on the property, or lodging unit, according to embodiment of the present disclosure.

Advantageously, the present disclosure assists in determining the optimal accommodation location for the visitors lodging. In addition, the present disclosure introduces the parent unit feature, which allows for the system to create one single booking for strategies with internal moves. Thereby, the present disclosure saves the expenses for extra reservation, such as the fixed fee from visitor's transaction fee, thus reducing the total amount of the booking. The computer-implemented system and method allows the visitor to locate the best possible lodging. Furthermore, the system finds the best price for the specified premises taking into account the visitor's criteria, thus giving priority to strategies with internal moves or without moves between different lodging unit. Furthermore, the system assures high occupancy rate of premises filling the gaps in a fragmented premises schedule. The system and method of the present disclosure help to find the best placement for the accommodation of the visitor in individual units and transfer between the units. The computer-implemented system and method provide an opportunity to find the optimal accommodation for the visitor. Also, the system increases the premises occupancy rate filling in the schedule gaps between previously occupied dates.

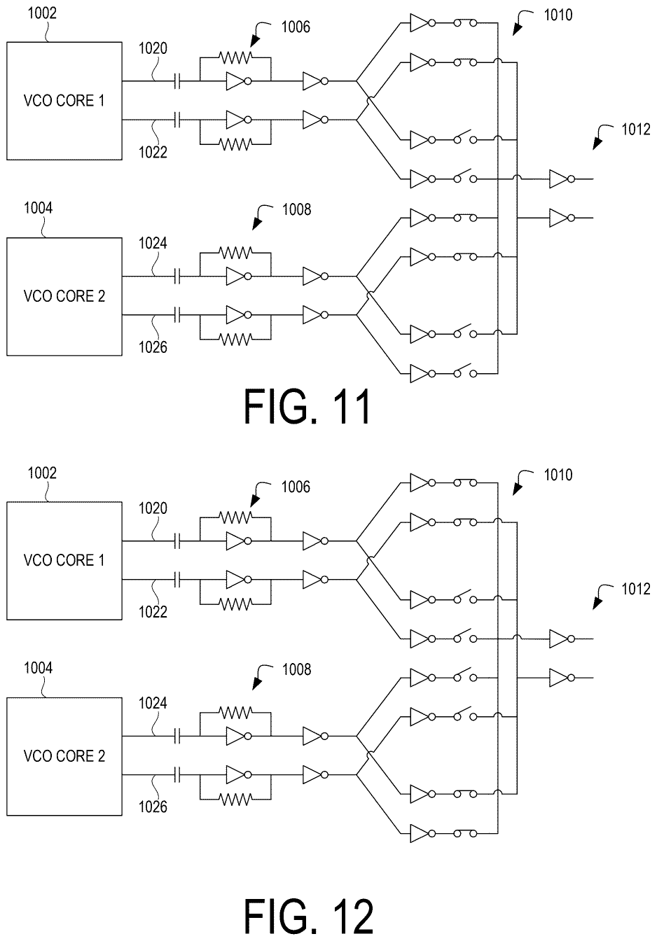

Referring now to FIGS. 11-17, possible approaches to accommodation planning are discussed. It should be appreciated that the approaches discussed below in regard to FIGS. 11-17 can be used together with the approaches described above. For example, a user may provide a query with various criteria, such as dates, locations, desired amenities, etc., as described above, and the query may be processed using some or all of the techniques described below.

In one embodiment, for efficient and effective implementation of finding optimal accommodation plan, a search engineering approach can be used. First, all candidate pairs and triples of units satisfying the condition of continuous stay are found, and then a solution is optimized using search results re-ranking. An accommodation plan is a native constraint satisfaction problem, but its simple case can be reduced to a resolution of constraints encoded as an inverted index. For simple accommodation plans, the constraint satisfaction is solved in one step. In terms of learning, running a query against an inverted index can be viewed as a nearest neighbor setting. In some cases, the classical inverted index may be extended by a vector database index.

An inverted index, commonly used in information retrieval systems like search engines, is a data structure that enables fast lookup of documents based on the terms they contain. Inverted index search works as follows:
1. Document Collection: First, there is a collection of documents that the user would want to be able to search through efficiently such as available accommodation dates. These documents can be web pages, articles, books, etc.
2. Tokenization: Each document is tokenized, meaning it's broken down into individual words or terms. During this process, common words like “and”, “the” etc., are often removed because they do not contribute much to the search process (these are called stop words).
3. Building the Index: For each term encountered in the documents, an inverted index is constructed. This index maps terms to the documents they appear in. For example, if the term “apple” appears in documents 1, 3, and 5, the inverted index will contain an entry for “apple” pointing to documents 1, 3, and 5.
4. Posting Lists: The mapping of terms to documents is often stored in what's called “posting lists.” A posting list for a term is essentially a list of document IDs (or other identifiers) where that term appears. So, for each term, you have a list of documents where that term occurs.
5. Search Process: When a user enters a search query, the query is also tokenized into individual terms. The search engine then looks up each term in the inverted index to find the documents that contain those terms.
6. Ranking: Once the documents containing the query terms are retrieved, they are often ranked based on relevance to the query. This ranking can be based on various factors such as term frequency, document popularity, proximity of terms, etc.
7. Presentation of Results: Finally, the search engine presents the ranked list of documents to the user, typically with the most relevant ones appearing at the top of the list.

To search for accommodation plan in real time, a specific index is prepared for pairs and triples of accommodations with their combined available dates. For example, a pair-wise index is shown in FIG. 11 for July 6 to July 16, based on the availability data from FIG. 4, with “A” indicating available and “B” indicating booked. An entry in the index of pairs for Units 6 and 7 is expected to indicate that all possible stays are available in the specified range. Notice that it is true only for the pair as the individual units are partially booked. It does not make sense to index units with very limited availability such as Units 1 and 2, as availability of the former supersedes that of the latter.

Such an index can be searched with range query directly, and for span query some adjustments for tokens need to be done to express the boundary between available (A) and booked (B). The advantage of range query approach is its simplicity and its applicability to the constructed pair-wise and triple-wise index such as FIG. 11. The advantage of span query is that it can handle an extended set of labels beyond just A and B, such as pending (P), unavailable (U) etc. Range queries and span queries are described in detail below.

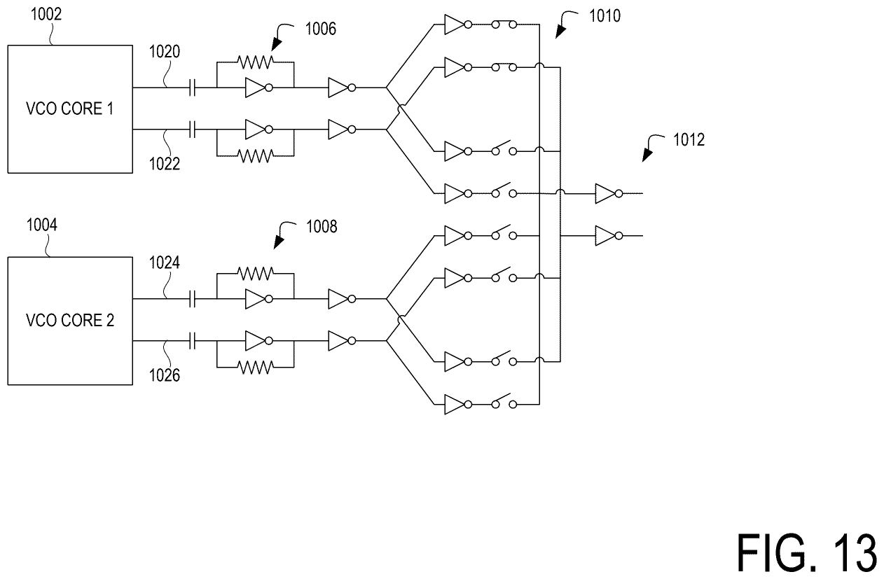

Referring now to FIG. 12, in one embodiment, a flowchart of a method 1200 for building an index of multiunit planning is shown. The method 1200 may be performed using the architecture 200 described above. The method 1200 begins in block 1202, in which an accommodation plan index is built, which can be done offline. The document fields may include, e.g., a list of available stay spans, attributes such as dining option, pet care, WiFi, etc., and location. In block 1204, all pairs of accommodations are iterated through. For each pair, if available stays for the accommodations overlap and if relocation from one property to the other is feasible, the pair is added to the search index.

In block 1206, pair-wise and/or triple-wise indices for range queries are formed. Boundary tokens may be added to express the boundary between available and booked days. Additionally or alternatively, pair-wise and/or triple-wise indices for span queries may be formed.

In block 1208, the generalization or amenities list is computed. A new generalized amenity list may be added to the pair-wise and/or triple-wise search index for range and span querying.

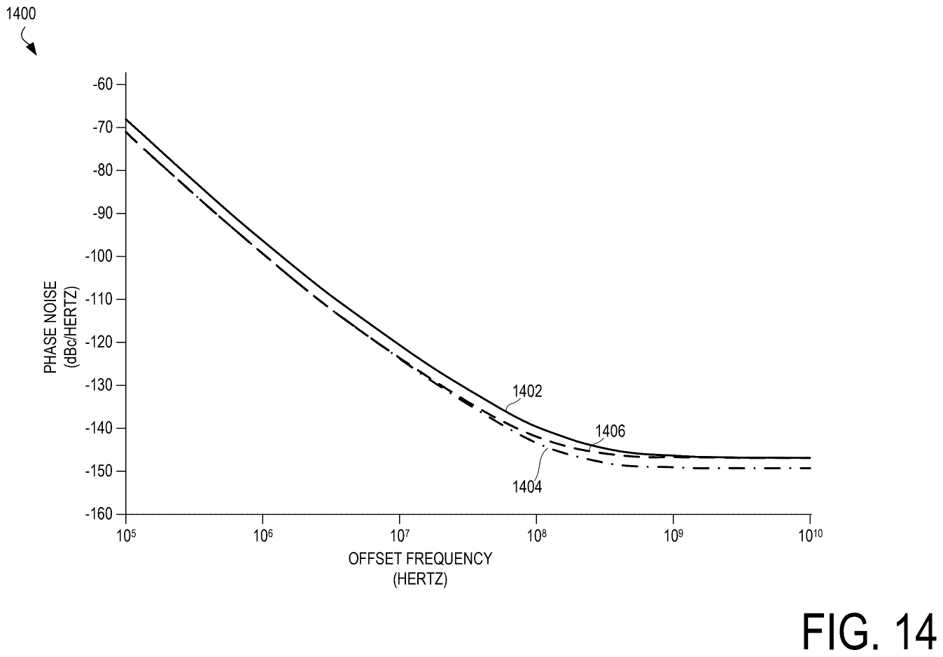

Referring now to FIG. 13, in one embodiment, a flowchart of a method 1300 for searching an index of multiunit planning is shown. The method 1300 may be performed using the architecture 200 described above. The method 1300 begins in block 1302, in which a user request is received. The system may first attempt to satisfy the user request with a single unit. If that is not successful, a query is formed for a pair-wise and/or triple-wise unit search. The query fields to be instantiated may include the list of available stay spans, attributes, and location.

In block 1304, a range query and/or span query is build for the requested range dates. A range query may be run against the pair-wise (and/or triple-wise) range index. If there are no results, a span query may be run against the span index. The list of pairs and/or triples of units that satisfy the temporal constraints may be obtained.

In block 1306, the normalized amenities for each list element is obtained by performing a generalization procedure. The search results may be ranked by desired amenities. In block 1308, the best ranked accommodation plans are provided to the user to choose from. The user's choice may be recorded, and the user's profile may be updated accordingly.

A range query is a query that demands all the points inside a set for a given interval. For such types of queries, a recursive transversal of a range tree is done by comparing each node and query interval. The time complexity of a range query is given as O(log n+k) and storage of O(n*log d−1 n), with d indicating the dimension of the space, n being the number of points in the tree and k being the number of points retrieved for the query.

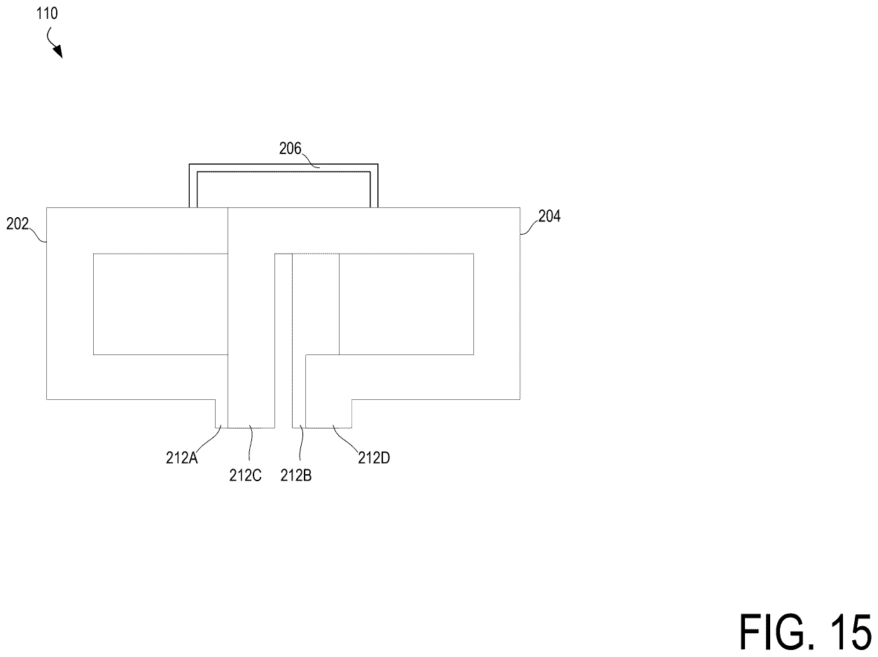

An example of a 1-Dimensional range tree is shown in FIG. 14. Every node other than the leaf node stores the highest value in its left subtree. Range queries offer prospective guests the flexibility to specify their preferences regarding price, availability, distance, rating, and room size when searching for accommodations. By allowing users to set ranges for these criteria, range queries help users find accommodations that best match their individual preferences and requirements, leading to a more personalized and satisfactory booking experience. Range queriers are implemented in search libraries like Elastic Search and SOLR.

Each node of the tree has two labels:
1. The range of points for which the node is responsible.
2. The maximum value of a point in the range of node.

To address a range query, recursive traversal of the tree is performed. The interval of query is compared to the range of each node in the tree. If the interval intersects the range of node, then the maximum value of the node's range is reported and if this is not the case then the traversal is continued on next dimension of the query interval which is the child node.

Span queries are useful for searching accommodations and multiunit rentals because they allow for more precise matching of phrases or sequences of words from user query to that of accommodation availability and descriptions. One example of an index for span querying for multiunit planing and required index structure will now be described. An availability of multiple properties can be encoded in an index as follows, using the format <date|availability>, availability={A (available), B (booked)}:
Days 1 2 3 4 5 6 7 8 9 10 11 12 13
Unit1 1A 2B 3B 4B 5A 6A 7B 8A 9B 10B 11A 12A 13A
Unit2 1A 2B 3B 4B 5A 6A 7A 8A 9B 10B 11A 12A 13A
Unit3 1A 2A 3A 4B 5B 6A 7B 8B 9A 10A 11A 12A 13B

To schedule an accommodation plan from 5 to 12 of the month, the following span query is formed:
SpanNearQuery(units: “5A”, units: “*A *B”, slop=X, ordered=true)
and SpanNearQuery (units: “*A”, units: “12A”, slop=Y, ordered=true),
X+Y=12−5.

In this search query expression, “units” is a field name in search index, units: “ . . . ” means that a specific value in this field is searched for, and ‘slop’ is a maximum number of tokens between span terms. Notice that a conjunction of two span queries is formed for each unit, and the condition that the sum of the slops is equal to 12−5 is enforced. Here span query syntax from Lucene library is used.

When a visitor selects two consecutive accommodations with certain requirements such as air conditioning and WiFi, respective property attributes need to be combined in some way. If one property satisfy this requirement better than the other, the multi-unit accommodation with the worst requirement value should be assigned, to avoid over-advertising of accommodation features. This assignment should be based on a set-theoretic general operation, such a least general generalization.

The term “least general generalization” refers to a concept within the domain of logic and more specifically, inductive reasoning. It describes the most specific generalization that can be made from a set of data or observations while still encompassing all these observations. When analyzing a set of examples or instances, the least general generalization identifies the narrowest statement or hypothesis that can be inferred from those examples while still being true for all of them. It captures the common characteristics shared by the examples without making any unnecessary assumptions or overgeneralizations. For example, if one observes that all of the accommodations are on the first floor, the least general generalization would be that “all observed accommodations are on the first floor”. This statement is the most specific generalization based on the observed data, as it accurately describes each instance without making broader assumptions about other types of accommodations. The least general generalization aims to strike a balance between being specific enough to accurately describe the observed data and being general enough to apply to all instances within that data set.

Semantic generalization (‘\hat{ }’) of amenities:
wifi \hat{ }comcast internet=wifi
pets allowed \hat{ }cats allow=pets allowed
dogs allowed \hat{ }cats allow=pets allowed

In some embodiments, a user's query may be processed by treating it as a constraint satisfaction problem (CSP). A CSP can be formally defined on a constraint network, which is a triple P={X; D; C}, where X=<x₁; . . . ; xₙ> is a set of n variables indexed by i, D={d(x₁), . . . , d(xₙ)} is the domain (range) of each xᵢ, and C={c₁, . . . , cₑ} is a set of e constraints indexed by j. A domain d(x₁) is a finite set of values that can be assigned to xᵢ. A constraint cⱼ is a pair <range(cⱼ); pred(cⱼ)>, where range (cⱼ)⊆X is the range (scope) of cⱼ specifying the variables involved in cⱼ, and pred(cⱼ) is the relation containing all the allowed value combinations (tuples) of variables in range(cⱼ). The cardinality of range(cⱼ), i.e. the number of variables involved in cⱼ, is called the arity of the constraint. C is assumed to contain only table constraints, i.e. all the allowed tuples for a constraint are explicitly listed as a table.

A solution to the constraint network is an assignment of all the variables such that all the constraints are satisfied. Solving a CSP is to find one solution of the constraint network, or prove no solution exists, i.e. the CSP is unsatisfiable.

If a plan can be described in words, planning is considered as token a generation problem, where tokens are produced by an LLM. Fulfilling user booking request is now viewed as a generation of a text (sequence of word tokens) describing the objects (accommodations) satisfying this booking request.

Transformer-based attention mechanism for solving multiunit planning will be described, as well as deep reinforcement learning-based and temporal constraint network-based algorithms.

Many real-world information retrieval (IR) queries involve specific requirements and constraints articulated by users in natural language (e.g., ‘a pair of nearby accommodations in San Diego’). In the past, addressing constraint satisfaction queries in IR was predominantly reliant on web searches or knowledge bases. However, recent advancements in large language models (LLMs) have shown promising initial capabilities in this area, albeit with lingering concerns regarding information accuracy and fabrication. Assessing LLMs through a constraint satisfaction framework aids in gauging and diagnosing their shortcomings in this domain.

Recent endeavors have focused on dissecting the mechanistic causes of inaccuracies satisfying booking requests when models fail to meet constraints. Studies have revealed a strong positive correlation between a model's attention to constraint tokens and the truthfulness of its responses. In one study, an SAT Probe was introduced, which is a method that probes self-attention patterns to predict constraint satisfaction and factual errors, enabling early error detection. Consequently, achieving improved attention structures within transformer-based LLMs is essential for effective constraint satisfaction planning. The efficacy of recommendation precision for a given booking request directly correlates with the quality of the network's attention structure.

Numerous queries and tasks can be analyzed within the context of constraint satisfaction. Adopting this framework offers a systematic approach to formulating queries with different levels of complexity by adjusting the constraints. An attention-based technique can be used to gain insights into the mechanics of open-source models and identify instances of failure by examining model internals. Beyond this, various tasks, such as planning, instruction, and controlled generation, can also be conceptualized as constraint satisfaction problems.

One way of measuring query complexity is using the notion of constrainedness, which views this as a function of the number of solutions for a given constraint. In similar spirit, it is worth measuring the complement of the ratio between the number of solutions S that satisfy the constraint and the total number of items in the domain N (higher constrainedness, more complex),

$$x = 1 - \frac{S}{N} .$$

Constrainedness can be regarded as the antithesis of query selectivity in database systems, representing the proportion of records that fulfill the query. Meanwhile, constraint popularity gauges the prevalence of entities within specific constraints, with more popular entities indicating lower complexity. Ideally, popularity would directly correlate with the frequency of information in training data. However, in many open-world scenarios, directly computing popularity or constrainedness is not feasible.

Therefore, constrainedness is defined as the count of potential solutions to the given problem within the output domain. For example, when presented with a query such as “Provide an accommodation name starting with the letter ‘A’ and ending with the letter ‘e’,” constrainedness is quantified by the number of words meeting these criteria within the total list of accommodations.

To implement CS based on LLMs, one strategy involves fine-tuning the LLM on domain-specific data sources to enhance its accuracy in answering questions within a particular domain. However, it has been observed that such methods can yield numerous inaccuracies. This issue partly stems from the inherent ambiguity of fine-tuning, which may not adequately modify the model to rectify previously learned erroneous information.

Another approach entails augmenting LLMs with additional, potentially pertinent information from external data sources. These techniques typically introduce supplementary data to the context considered during pretraining. Although this avenue of research has marginally enhanced the accuracy of LLMs, it fails to address the fundamental issue of erroneous and irrelevant information within these models. It remains uncertain whether the inclusion of more relevant information effectively eliminates inaccuracies stored in the model. Moreover, sourcing sufficient relevant data, especially for less common entities like infrequently booked accommodations, poses a significant challenge.

LLMs are renowned for encapsulating extensive knowledge, making them invaluable for addressing text-based CSPs. However, the understanding of how LLMs process booking queries and generate errors is still limited. To fulfill booking requests accurately using LLMs, it is crucial to grasp how LLMs might generate inaccuracies due to hallucinations, particularly in recommending accommodations.

Current methods for interpreting LLM outputs in response to accommodation request fall into two main categories:
(1) treating the LLM as a black-box and posing queries regarding generated accommodation recommendation, or
(2) utilizing white-box internals to dissect the mechanistic process of LLMs in handling accommodation requests.

While both approaches hold potential and represent paths of exploration, each harbors inherent limitations. Black-box methodologies probe the consistency of an LLM's assertions by employing follow-up questions with other LLMs or having the LLM itself evaluate its responses during constraint satisfaction. However, explanations provided by LLMs have exhibited unreliability or may convey conflicting signals, such as when an LLM produces an answer and subsequently acknowledges its inaccuracy. Moreover, these approaches rely on multiple generations from LLMs, which could prove prohibitively expensive for practical implementation in a constraint satisfaction session.

Mechanistic white-box approaches investigate the internal mechanisms of LLMs to dissect factual recall while navigating the hypothesis space of CSP. Geva et al. (2023) focus on facts with the (subject, relation, object) structure (e.g. accommodation in <Dubai, capital of, UAE>) and propose insightful mechanisms of how an LLM recalls a fact. They suggest that the Multi-Layer Perceptron (MLP) layers store facts, and attention layers transfer factual information from the subject tokens. These works focus on when the model can produce factually correct and constraint-satisfiable responses.

CSP imposes a set of constraints that the LLM's responses must satisfy. To predict constraint satisfaction, the attention to the constraint tokens in an LLM is tracked. Accommodation intent queries can be conceptualized as CSPs, where these queries consist of constraints that completions must adhere to for factual accuracy. Understanding how properties of constraints, like popularity, intersect with the correctness of LLMs is crucial, as is delving into the mechanisms of constraint satisfaction. It turns out that the level of attention directed towards constraint tokens in LLMs correlates with factual correctness, with lower attention suggesting inaccurate responses.

A booking request is specified by a set of constraints C={(C₁, V₁), . . . (C_{K}, V_{K})} where C_{K}∈V⁺ indicates the sequence of tokens for the constraining entity k, and V_{K}: V+→{0, 1} is a checker that takes a set of generation tokens as the input and verifies whether the constraint numbered by k is satisfied. In this approach, a LLM completion of Y as a factual booking request error if ∃k∈[K]: Vₖ(Y)=0, that is, if there is a constraint from the booking request in the factual query that the response does not satisfy. Otherwise, the booking request satisfiability is set to ‘factually correct’.

To improve the LLM handling of CSP, the attention to the constraint tokens is controlled:

$${a}_{c , T}^{l , h} = {A}_{c , T}^{l , h} ( {x}_{c}^{l - 1} {W}_{V}^{l , h} ) {W}_{O}^{l , h} ,$$

where

$${a}_{c , T}^{l , h} ∈ {R}^{d}$$

indicates the attention contribution from a constraint token c through a head h to the final token T (where the T+1-th token will be generated). The total attention contribution to T is then

$${a}_{c , T}^{l} = {\sum }_{h} {a}_{c , T}^{l , h} .$$

When the constraint is applied to multiple tokens denoted by the set C, the maximum value across all constraint tokens is selected

$${A}_{C , T}^{l , h} = {max}_{c ∈ C} {A}_{c , T}^{l , h} .$$

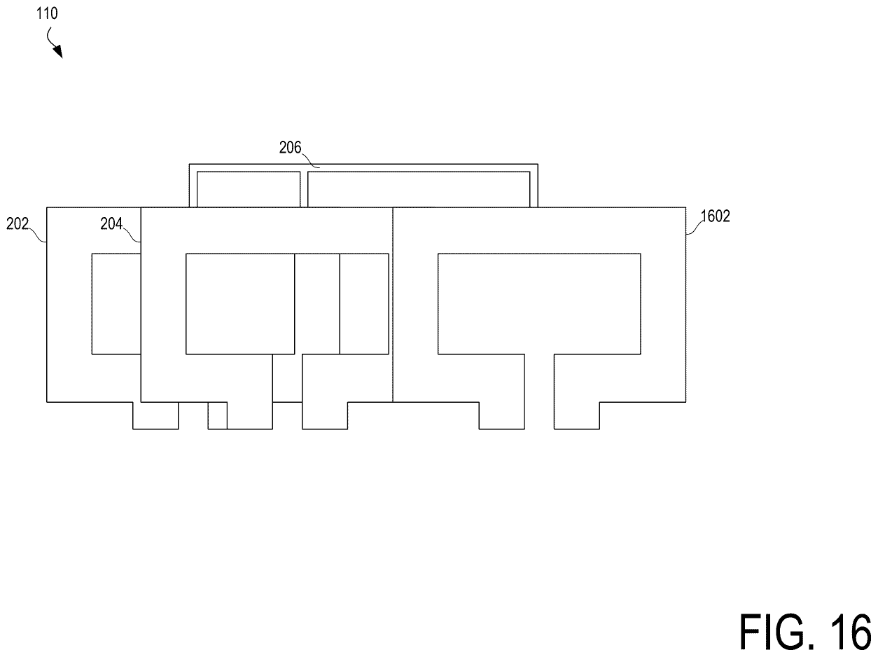

Referring now to FIG. 15, in one embodiment, a flowchart for a method 1500 for LLM-based accommodation planning is shown. The method 1500 may be performed using the architecture 200 described above. The method 1500 begins in block 1502, in which text and numerical parameters of objects (e.g., accommodations) are represented as a training corpus for LLM fine-tuning.

In block 1504, L layers of a transformer network are built that convert input token embedding to a sequence of hidden states. In block 1506, the LLM is pre-trained, such as by encoding the ontology into an embedded representation using a long short-term memory (LSTM).

In block 1508, a multilayered perceptron contribution is combined with attention contribution for each token at each network layer. In block 1510, the LLM is used to produce predicted probability distribution for the next token.

In block 1512, an attention operation updates each token state using tokens at each position. In block 1514, newly generated tokens are delivered as a result of booking order.

As LLMs are developed through pretraining, it's logical to investigate methods that integrate semantic constraints during this stage to foster consistent LLMs. However, pretraining usually requires significant time and computational resources. To streamline the process, researchers often utilize a relatively rapid technique called fine-tuning. This involves adjusting a pretrained LLM by training it with additional information while retaining its pretrained weights as initial values. Techniques for crafting or modifying an LLM to adhere to a set of constraints through the combination of pretraining and fine-tuning are described below.

Semantic properties and constraints within a domain are frequently encapsulated in ontologies. An ontology comprises a collection of facts, where each fact is represented as a triple in the form of (subject, relationship, object), alongside a set of constraints governing these facts. Triples within an ontology introduce concepts (e.g., Accommodation types) and their instances (e.g., Visitor's Inn), as well as delineate relationships between different domain concepts (e.g., Motel-8 is a motel). Constraints in an ontology delineate the conditions that concepts and relationships must adhere to, such as the transitive property of “is-a.” These constraints are typically articulated within a subset of first-order logic, such as description logic. In essence, each constraint stipulates that if certain concepts satisfy specific conditions (i.e., premises), they must also fulfill other conditions (i.e., conclusions). For instance, for is-a relation, we have for all concepts □, □, □, if (□, □□-□, □) and, (□, □□-□, □), then (□, □□-□, □). It is important for an LLM to encapsulate both the facts and the constraints on those facts in a domain to provide consistent results. An LLM might not learn the facts from the textual data over which it is pretrained. It could be because some facts are not in the text or do not appear in closely related text spans and contexts. Constraints in an ontology represent semantic meaning of concepts and relationships in the domain. This information does not often appear explicitly in the data used to pretrain LLMs, therefore, LLMs might not learn them during pretraining. Thus, the goal is to create LLMs that contain and follow both facts and constraints in a given ontology.

Integrating structured information into LLMs presents challenges due to their training on unstructured data. One approach involves supplementing the training data with textual ontology information, such as “Accommodations in Boston area are expensive in comparison to national average.” However, translating facts and constraints into text introduces two issues. Firstly, domains with numerous semantic constraints may lead to augmented training data exceeding maximum sequence lengths, typically capped at 512 in most models. Secondly, converting structured data into unstructured text may cause the model to perceive this information merely as additional context, potentially overlooking higher-order constraints essential for semantic comprehension within the domain.

To address these challenges, constraint reduction techniques can be employed. One method involves reasoning over the constraints to identify a minimal set, although it does not guarantee compliance with the maximum sequence length restriction. Alternatively, encoding ontology information into an embedded representation using an LSTM, integrated via a gating function, enables the LLM to control which information augments the input, effectively limiting the sequence length. However, this approach may not be optimal for incorporating constraints, potentially leading to information loss, and is better suited for enhancing input with additional facts rather than filtering incorrect information.

These methods struggle to fully incorporate ontology in a manner that preserves its semantic information, underscoring the complexity of integrating higher-order constraints into LLMs.

Backtracking search algorithms are commonly employed for solving CSPs, with the effectiveness of such searches heavily dependent on the selection of variable ordering heuristics. Currently, prevailing heuristics are mainly manually-designed, drawing from expert knowledge. One approach is to leverage deep reinforcement learning to autonomously discover new variable ordering heuristics better suited for specific classes of booking accommodation requests, thereby reducing reliance on manually-designed features and heuristics. Directly optimizing the size of the search tree proves challenging for learning. One alternative is to optimize the expected cost of reaching a leaf node in the search tree instead. To capture the intricate relationships among variables and constraints, a representation scheme grounded in Graph Neural Networks is devised, capable of handling CSP instances of varying sizes and constraint arities. Previous experimental results on random CSP instances demonstrate that their learned policies outperform classical hand-crafted heuristics in reducing the search tree size, achieving reductions of up to 10% on small and medium-sized instances. Moreover, even without additional training, these policies seamlessly generalize to larger and more challenging instances than those encountered during training, resulting in even greater reductions in search tree size, up to ⅙.

Recently, LMMs have demonstrated promise in learning algorithms to tackle NP-hard problems like routing, graph problems, and the Propositional Satisfiability Problem (SAT). Their effectiveness stems from the ability of Deep Neural Networks (DNNs) to learn useful patterns within a class of problem instances, even those that may not be easily specified by human experts, through supervised or reinforcement learning (RL). Building on this success, the question has been posed: “Can LLMs be utilized to discover improved variable ordering heuristics for a class of CSP?” This task is non-trivial due to several challenges:
(1) Given the exponential worst-case complexity of CSP, obtaining a large amount of labeled training data (e.g., optimal search paths) is impractical, making it difficult to apply supervised learning methods.
(2) CSP instances vary in size in terms of the number of variables and constraints, with differing constraint arities (i.e., the number of variables involved). Hence, it's essential to devise a deep representation scheme capable of effectively handling CSP instances of varying sizes and constraint arities.

One solution is to design a deep reinforcement learning algorithm which tries to make the optimal variable ordering decisions at each decision point to minimize the search tree size. More specifically, variable ordering in backtracking search is modeled as a Markov Decision Process (MDP), where the optimal policy is to select at each decision point the variable with the minimum expected number of search nodes. The DRL agent can optimize its policy by learning from its own experiences of solving CSP instances drawn from a distribution, without the need of supervision. However, such direct formulation could cause inefficiency and inconvenience to the learning mechanism, since learning must be delayed until backtracking from a search node.

To resolve this issue, the search paths can be considered as originating from a node as separate trajectories, and the expected number of remaining nodes to reach a leaf node can be minimized. The internal states of the search process are represented based on Graph Neural Network (GNN), which can process CSP instances of any size and constraint arity, and effectively capture the relationship between the variables and constraints.

The process of backtracking search can be likened to navigating a search tree in a depth-first manner, dynamically constructing it as the search progresses. At each node, the algorithm picks an unassigned variable based on a chosen heuristic for variable ordering. It then generates multiple child nodes by applying a branching strategy, creating mutually exclusive and exhaustive branching constraints and performing constraint propagation (CP). CP eliminates inconsistent values based on current branching decisions, significantly reducing the search space and enhancing computational efficiency. Each search node represents an instantiation of the original CSP instance being tackled, maintaining the same constraints but with smaller domains (excluding branching constraints). If a variable's domain becomes empty after constraint propagation, the node becomes a dead-end as no feasible solution can be reached with the current branching decisions, prompting the algorithm to backtrack. Search concludes upon finding a solution or fully traversing the search tree, indicating the instance is unsolvable. Therefore, the leaf nodes of the search tree comprise dead-ends and any feasible solutions, if present.

A CSP algorithm for finding an accommodation is now outlined, where accommodations' attributes are described by a constraint network P. Given a constraint network P, let Nc(j)={j|xᵢ∈range(cⱼ)} be the indexes of variables that are in the range of a constraint cⱼ, and Nv(i)={i|xᵢ∈range(cⱼ)} be the indexes of constraints where a variable xᵢ is involved in. The current status of variables and constraints are characterized by raw feature vectors Xᵢ and Cⱼ, each with dimension pᵥ and p_{c}. The GNN computes a p-dimensional embedding μᵢ and uⱼ for each variable xᵢ∈X and constraint cⱼ∈C. These embeddings are first initialized by linearly transforming the respective raw feature vectors, i.e.

$${μ}_{i}^{{( 0 )}^{⎵}} = {X}_{i} {w}_{v} and {ν}_{i}^{( 0 )} = {C}_{i} {w}_{c} ,$$

where wᵥ∈ [symbol] and w_{c}∈ [symbol] , are learnable parameters. Then these embeddings are updated by performing K iterations of embedding aggregation operations among the variables and constraints, based on the underlying hypergraph structure.

At each iteration k=1, . . . , K:
(1) Embedding of each constraint cⱼ is first updated by aggregating embeddings from the related variables in N_{c}(j). More specifically, we use element-wise summation as the aggregation function, the result of which is fed into a Multilayer Perceptron (MLP) MLPᵥ to get the updated embedding of cᵥⱼ, along with its embedding in the previous round and its raw feature vector. This procedure is shown as follows:

$${ν}_{j}^{( k )} ← M L {P}_{v} [ {\sum }_{i ∈ {𝒩}_{c} ( j )} {μ}_{i}^{( k - 1 )} : {ν}_{j}^{( k - 1 )} : {C}_{i} ]$$

where [. : .] is the concatenation operator. The input and output dimension of MLPᵥ are 2p+p_{c} and p, respectively.
(2) Embedding of each variable xi is updated by aggregating embeddings of the related constraints in Nᵥ(i), based on similar procedure shown below:

$${μ}_{i}^{( k )} ← M L {P}_{c} [ {\sum }_{j ∈ {𝒩}_{v} ( i )} {v}_{i}^{( k )} : {μ}_{i}^{( k - 1 )} : {X}_{i} ]$$

The training algorithms maintains two networks:
(1) online network \hat{Q}_{w}, and
(2) target network

$${\hat{Q}}_{\overline{w}} .$$

is a periodical copy of (1)

At each state s, the RL algorithm selects an action at using the □-greedy strategy according to the online network, and the experience (s, a, s′, r, T) is added to an experience reply buffer R with memory size M, where T=T(s′) is a binary indicator of whether s′ is a terminal state. Then a mini-batch of B transitions is sampled from R to update the parameters of the online network \hat{Q}_{w} by performing gradient decent to minimize the squared loss between \hat{Q}_{w}(s,a) and the following target:

$$y = r + γ {\hat{Q}}_{\overline{w}} ( {s}^{′} , {arg min}_{{a}^{′} ∈ A ( {s}^{′} )} {\hat{Q}}_{w} ( {s}^{′} , {a}^{′} ) )$$

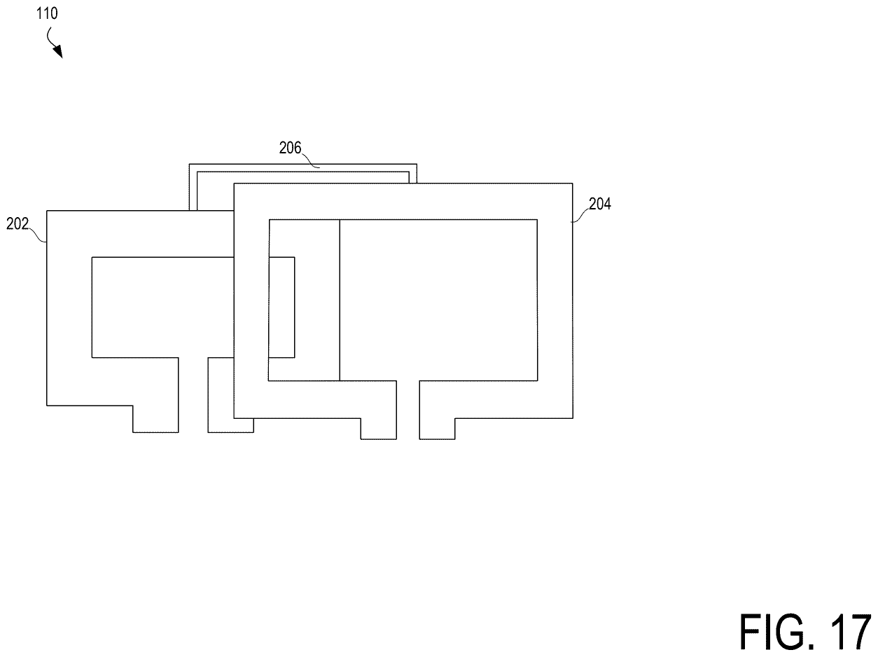

Referring now to FIG. 16, in one embodiment, a flowchart of a method 1600 for deep relational learning-based constraint satisfaction problem for accommodation planning is shown. The method 1600 may be performed using the architecture 200 described above. The method 1600 begins in block 1602, in which a formulae constraint network for the set of accommodations in a given area is formulated offline

In block 1604, a user booking request is formulated. A branching strategy is implemented, such as enumerating booking request criteria such as location, price, date, etc. A backtracking search may be performed.

In block 1606, deep relational learning is employed to learn value ordering heuristics to choose a value for a selected variable to initiate. For example, one approach could be to first search by price, then by date, then by amenities, then by sub-location.

In block 1608, once the order of variables is obtained, a search is performed. In block 1610, the search results are provided to the user.

Much of the work in temporal querying and temporal reasoning has used temporal formalisms based on points anchored in absolute time. The available data in such work consist of discrete coded events with known times, such as previous stay at accommodation information. Typically, events are represented as points or pairs of points, in which each point is a time stamp stored in a database. Previous work addresses temporal abstraction: recognizing temporal patterns among the time stamps and determining what can be inferred based on the temporal semantics of the events.

A corpus of research on temporal intervals to support temporal abstraction and temporal querying explore qualitative constraints which can be defined by Allen's interval relationships. One interval can occur before, meet, overlap, start, occur during, finish, or be equal to another interval. In addition to this set of relationships, one can create composite disjunctions. For example, a composite disjunction in a narrative may consist of an episode of check-in procedure at a property that occurred before or after (but not during) a specified check-in period for this property.

LLM converts text (narrative) to a formal representation. The temporal information in narrative text from is mapped into the model. Narrative reports describe accommodation check-in and other events and contain temporal assertions about those events. The events have a start and a finish (whose time may or may not be known). A model may contain time points; constraints, which specify the temporal relationship between pairs of points; and temporal intervals, which comprise a pair of time points and a definitional constraint that the start point must not follow the finish point. Events are mapped into intervals and assertions to constraints. Individual constraints apply to points, which imply constraints on the intervals. A constraint satisfaction problem is defined by time points and constraints (inequalities between points). A time interval comprises a pair of points and a constraint encoded each event as a descriptive phrase (such as the latest train one can take to arrive to a given accommodation) and a unique event identifier and modeled it as an interval. Instantaneous events are constrained to have equal start and finish times.

A number of temporal assertions can be inferred from the context of the accommodation request. Events such as check in and stay rules violation can be occurring at the same time or after events mentioned in preceding sentences, unless stated otherwise. The advantages of representing temporal information as a simple temporal problem are that computation is tractable, the representation is relatively simple, and one can leverage an extensive corpus of research on simple temporal problems. The interval algebra is useful for querying the encoded result. Defining an algebra should be straightforward, however, and should benefit from previous work in this area.

With the multivariable fuzzy temporal profile formalism, it is possible to represent and identify certain monitoring criteria defined as a pattern of findings that consists of the appearance of a set of morphologies over several physiological variables, and a set of relations between them. This model is an extension of the Fuzzy Temporal Profile approach, which allows a finding to be represented as a morphology described over a single variable. The fact of being able to relate the occurrence of different available attributes among accommodation variables is of great importance, as often the appearance of an attribute over a single variable, which on its own may not be a major decision making factor, may well be of interest to the user if it appears to be related with other attributes over different variables which do not seem to be definitive when considered in isolation either.

An MFTP comprises a set of points (defined over the temporal evolution of the monitored user intents in accommodation booking request) that are relevant for the booking recommendation, and a set of flexible constraints that limit the evolution of the attributes of user interest between them. These constraints are represented by means of fuzzy sets, allowing a pattern to be modelled as a flexible set of possible evolutions of the variables.

Given a universe U, the concept of fuzzy value C is defined by means of a possibility distribution π^{C} defined over U. Given a precise value u∈U, π^{C}(u)∈[0; 1] represents the possibility of C being precisely u. Given as universe the set of real numbers R, a fuzzy number is a normal and convex fuzzy value. A fuzzy value C is normal if and only if ∃ᵤ∈R|π^{C}(u)=1. C is said to be convex if and only if ∀u, u′, u″∈R, u′∈[u, u″], π^{C}(u′)≥min{π^{C}(u), π^{C}(u″)}.

By means of p_{c} define a fuzzy subset C̅ of R, which contains the possible values of C, where C̅ is a disjoint subset, in the sense that its elements represent mutually excluding alternatives for C. The fuzzy set C is characterized by a membership function μ_{c}:R→[0; 1] that associates with each element u∈R a real number in the interval [0; 1]; this is named the degree of membership of u in C. One can obtain a fuzzy number C from a flexible constraint given by a possibility distribution π^{C}, which defines a mapping from R to the real interval [0; 1]. A fuzzy constraint can be induced by an item of information such as “x has a high value”, where “high value” will be represented by π^{C=high}. Given a precise number u∈R, π^{C=high}(u)∈[0; 1] represents the possibility of C being precisely u; i.e., the degree with which u fulfills the constraint induced by “high value”.

Time is treated as being projected onto a one-dimensional discrete axis T={t₀; t₁; . . . ; tₛ}, where tₛ represents a precise instant. P={P¹; . . . ; P^{m}} is defined as the set of accommodation variables obtained from the booking request. Each of the accommodation variables P^{P}∈P obtained by a sampling process, in the form of a temporal Serres

$${X}_{i}^{p}$$

where

$$\begin{matrix}p \\ [ s ]\end{matrix}$$

is the value of P^{p} at the temporal instant

$${t}_{[ s ]}^{p} .$$

A significant point

$${P}^{p} = \{ ( \begin{matrix}p \\ [ s ]\end{matrix} , {t}_{[ s ]}^{p} ) ; s ∈ N \} ,$$

is defined as being associated with an accommodation variable P^{p}, as the pair formed by a variable of the domain

$${V}_{i}^{p}$$

and a temporal variable

$${T}_{i}^{p} {X}_{i}^{p} = < {V}_{i}^{p} , {T}_{i}^{p} > .$$

Significant points represent points of the temporal evolution of the variable of special interest for the user. In the absence of any constraints, the variables

$${V}_{i}^{p} and {T}_{i}^{p}$$

of the significant point

$${X}_{i}^{p}$$

may take any precise value

$$\begin{matrix}i \\ p\end{matrix} and {t}_{i}^{p} ,$$

respectively, where

$$( \begin{matrix}i \\ p\end{matrix} and {t}_{i}^{p} ) ∈ {P}^{p} .$$

A constraint

$${L}_{ij}^{pq}$$

is defined over two temporal variables

$${T}_{i}^{p} and {T}_{j}^{q}$$

by means of the normal, convex possibility distribution

$${π}^{{L}_{ij}^{pq}} ( h )$$

over Z, such that

$$∀ h ∈ Z : {π}^{{L}_{ij}^{pq}} ( h ) ∈ [ 0 ; 1 ] .$$

Given a precise temporal duration

$${h}_{ij}^{pq} , {π}^{{L}_{ij}^{pq}} ( {h}_{ij}^{pq} )$$

represents the possibility of the temporal duration between

$${T}_{1}^{p} and {T}_{j}^{q}$$

being precisely

$${h}_{ij}^{pq}$$

thus

$${L}_{ij}^{pq}$$

represents the fuzzy temporal duration between

$${T}_{i}^{p} and {T}_{j}^{q} .$$

In the absence of any other constraints, the precise value assignations

$${t}_{i}^{p} = {T}_{i}^{q} and {t}_{j}^{q} = {T}_{j}^{q}$$

will be possible if

$${π}^{{L}_{ij}^{pq}} ( {t}_{j}^{q} - {t}_{i}^{p} ) > 0 .$$

With the constraints

$${L}_{ij}^{pq}$$

it is possible to model linguistic descriptions that limit the fuzzy temporal duration between a pair of normally represents a temporal extension during which the value or rate of change of the variable is constant. When events are defined over different variables, L_{if}^{pq} describes the temporal layout of the two findings that form part of the global pattern, thus allowing a fuzzy temporal constraint network to be defined between all the components of the pattern.

Following the bibliography on temporal constraint networks, and with the aim of obtaining a more compact notation, the origin significant point

$${X}_{0}^{p} = ( {V}_{0}^{p} , {T}_{0}^{p} )$$

is defined, which let the temporal constraints (e.g. “check in a little after 7:30 μm”) and value constraints (e.g. “temperature of approximately 75 F”) be represented as constraints of duration and increment, respectively, relating to the origin significant point. Any arbitrary value can be assigned to

$${X}_{0}^{p} .$$

A Multivariable Fuzzy Temporal Profile (MFTP) M=<W^{M}, X^{M}, R^{M}> is defined over the set of accommodation variables P as a finite set of MFTPs W^{M}={M₁, . . . , Mₛ}, a finite set of significant points

$${X}^{M} = \{ {X}_{{i}_{1}}^{{p}_{1}} , {X}_{{i}_{2}}^{{p}_{2}} , … , {X}_{{i}_{g}}^{{p}_{g}} \}$$

and a finite set of constraints

$${R}^{M} = \{ {R}_{ij}^{pq} , 1 \leq p , q \leq m ; 0 \leq i \leq {n}^{p} , 0 \leq j \leq {n}^{q} ij ;$$

these constrains are applied to W^{M} and X^{M}.

Here m is the number of parameters involved in M, n^{p} and n^{q} are the number of significant points defined over P^{p} and P^{q}, respectively. Hence an accommodation search problem is formulated as a match of user intent MFTP against an accommodation MFTP.

MFTP provides for a hierarchical organization of matching task, where a pattern M forms a processing level that incorporates a set of user intents detected in the previous processing level.

Identifying a pattern M over the set of the accommodation variables P={P₁; . . . ; Pₘ} can be formulated as finding a solution to the fuzzy constraint network defined by M. A network solution is built by means of the assignment

$${A}_{i}^{p}$$

of a sample of the evolution of Pₚ to each significant point

$$A = {A}_{{i}_{1}}^{{p}_{1}} , {A}_{{i}_{2}}^{{p}_{2}} , … , {A}_{{i}_{g}}^{{p}_{g}}$$

that satisfy the set of constraints that make up M, with a degree higher than zero.

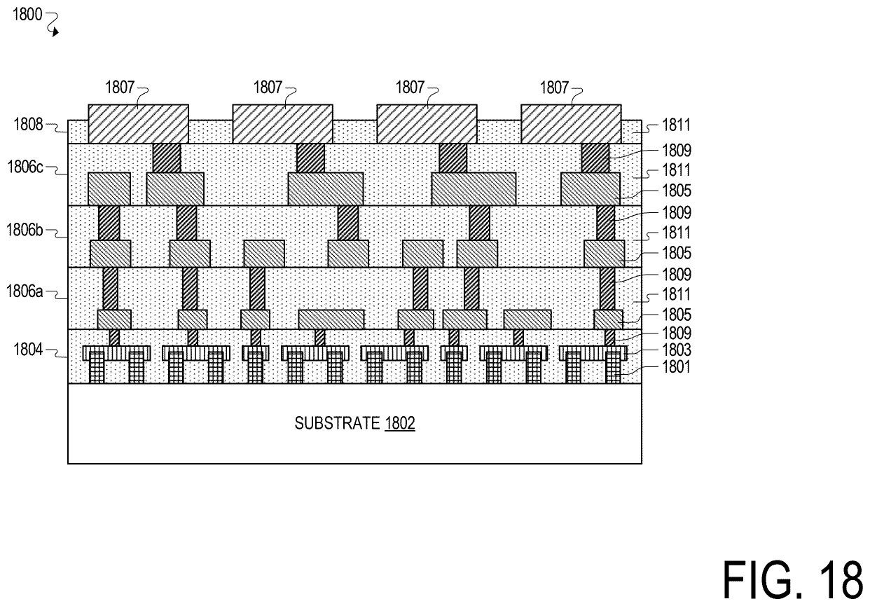

Referring now to FIG. 17, in one embodiment, a flowchart of a method 1700 for fuzzy pattern matching for fulfilling accommodation requests is shown. The method 1700 may be performed using the architecture 200 described above. The method 1700 begins in block 1702, in which the hierarchy of processing level to compute patterns for accommodation intent is prepared offline. In block 1704, a user booking request is provided, optionally with its evolution in previous unsuccessful search sessions. The set of MFTPs is formed, the set of significant points is formed, and the set of constraints acceptable to the user is formed.

In block 1706, deep relational learning is employed to learn value ordering heuristics to choose a value for a selected variable to initiate. For example, the system may first search by price, then by date, then by amenities, then by sub-location.

In block 1708, a graph representation of MFTP is built, using significant points and constraints. Patterns for match are produced. In block 1710, once the order of patterns to be applied is obtained, the pattern match is performed. In block 1712, pattern-matched accommodations are returned to the user.

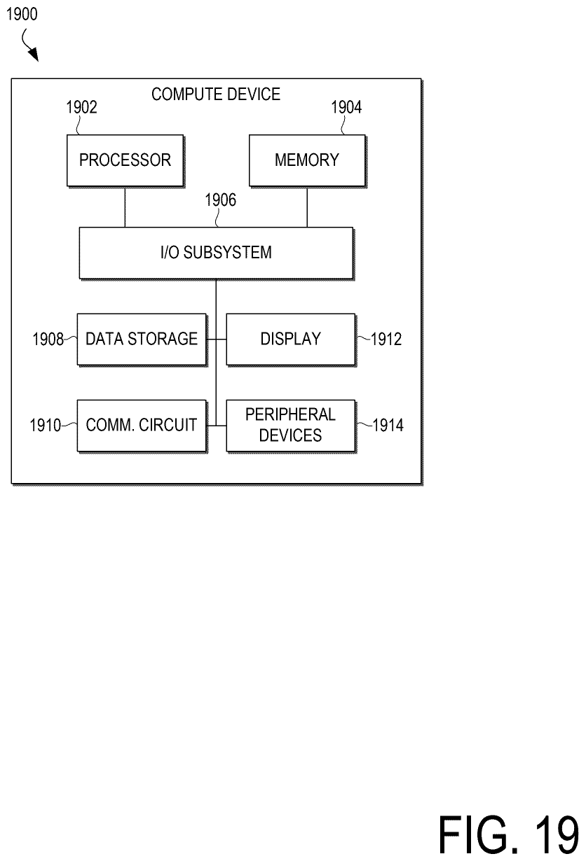

Referring now to FIG. 18, in some embodiments, another algorithm can be used to identify suitable accommodations. To solve the problem of finding a path from the left end to the right end of a grid, similar to navigating a maze, a breadth-first search (BFS) algorithm can be used. Such an algorithm is particularly well-suited for finding the shortest path in an unweighted grid. A step-by-step guide on how to implement such an algorithm is presented below.

At the outset, the BFS is initialized. A queue is created to keep track of the nodes to be explored. A set or a boolean array is created to keep track of visited nodes. The starting node (all nodes on the left end of the grid) is enqueued and marked as visited.

The BFS loop then begins. A node is dequeued from the front of the queue. If this node is on the right end of the grid, then a path has been found, and the algorithm can terminate. If this node is not on the right end of the grid, then the algorithm continues.

For each neighboring node (i.e., adjacent node) of the current node, the cost to reach the neighbor is calculated. If the neighbor has not been visited and is not blocked, it is marked as visited and enqueued. If the queue is exhausted without reaching any node on the right end, then no path exists.

More detailed pseudo-code for the BFS algorithm is presented below:

```
def bfs_find_path(grid, start_nodes, end_condition):
  from collections import deque
  queue = deque( )
  visited = set( )
  # Initialize the queue with the start nodes
  for start in start_nodes:
    queue.append(start)
    visited.add(start)
  while queue:
    current = queue.popleft( )
    # Check if the right end has been reahed
    if end_condition(current):
      return True # Path found
    # Explore the neighbors
    for neighbor in grid[current]:
      if neighbor not in visited and not grid.is_blocked(neighbor):
        visited.add(neighbor)
        queue.append(neighbor)
  return False # No path found
```

The algorithm starts by initializing the BFS with all nodes on the left end of the grid as the starting points. These nodes are enqueued and marked as visited. The BFS explores each node level by level. For each node, it checks if it is on the right end. If it is, a path has been found and the algorithm returns ‘True’. If not, the algorithm explores all unvisited, non-blocked neighbors and enqueues them for further exploration. If the queue becomes empty and no right end node has been reached, the algorithm concludes that no path exists and returns ‘False’.

This BFS-based algorithm ensures that the shortest path (if any) is found efficiently. It is robust against blocked paths and will explore all feasible routes until it either finds a path or exhausts all possibilities.

The algorithm can be modified to involve dynamic programming. To do so, a mechanism can be incorporated to keep track of the minimum cost at each node, and a penalty function can be used for changing node categories. Such an approach will ensure that strategies are continuously updated and filtered to find the optimal path with the minimum cost. Such an algorithm is described in more detail below, as shown in the method 1800 in FIG. 18.

In block 1802, the BFS is initialized with a Dynamic Programming Table. A queue is created to keep track of the nodes to be explored. A dictionary ‘min_cost’ is created to keep track of the minimum cost (multiunit value) to reach each node. The starting nodes are enqueued with a cost of 0 and marked as visited with their respective costs.

The initially empty list of best paths is created, which is updated once a comparably good path is found. The list of strategies (penalty functions) is created.

The BFS loop with dynamic programming can then begin in block 1804. A node from the front of the queue is dequeued along with its current cost. In block 1806, if this node is on the right end of the grid, then a path has been found, and the minimum cost can be updated in block 1808, if necessary. Otherwise, the method 1800 proceeds to block 1810.

In block 1810, for each neighboring node (i.e., adjacent node) of the current node, calculate the cost to reach the neighbor, including any penalties for changing node categories. In block 1812 and 1814, for each neighboring node, if this calculated cost is less than the current known cost for the neighbor, update the cost and enqueue the neighbor.

In 1816, if the queue is exhausted without reaching any node on the right end, then the method 1800 proceeds to block 1818, and no path exists. If the queue is not exhausted, the current path is added to the list of best paths in block 1820 and a new strategy is applied and the method proceeds to the next accommodation in block 1822. The method 1800 then loops back to block 1806.

Pseudo-code Implementation for such an algorithm is below:

```
  def bfs_with_dp_find_path(grid, start_nodes, end_condition,
list_of_penalty_func)=> list_best_paths:
    from collections import deque, defaultdict, list
    list_best_paths = [ ]
    for penalty_func in list_of_penalty_func:
      queue = deque( )
      min_cost = defaultdict(lambda: float(′inf′’))
      # Initialize the queue with the start nodes and cost 0
      for start in start_nodes:
        queue.append((start, 0))
        min_cost[start] = 0
      while queue:
        current, current_cost = queue.popleft( )
        # Check if the right end has been reached
        if end_condition(current):
          continue # Continue to find potentially cheaper paths
        # Explore the neighbors
        for neighbor in grid[current]:
          if grid.is_blocked(neighbor):
            continue
          # Calculate the new cost to reach this neighbor
          new_cost = current_cost + grid.cost(current, neighbor) +
penalty_func(current, neighbor)
          # If the new cost is lower, update and enqueue
          if new_cost < min_cost[neighbor]:
            min_cost[neighbor] = new_cost
            queue.append((neighbor, new_cost))
      # Find the minimum cost to any node on the right end
      min_final_cost = float(′inf′)
      for node in min_cost:
        if end_condition(node):
          min_final_cost = min(min_final_cost, min_cost[node])
      result = min_final_cost if min_final_cost != float(′inf′) else None
      list_best_paths.append(result)
    return list_best_paths
  # Example usage:
  # Assuming ‘grid‘ is an adjacency list representation of the grid
  # and ‘is_blocked‘ is a method that checks if a node is blocked
  # and ‘cost‘ is a method that returns the cost between two nodes
  # and ‘penalty_func‘ is a function that calculates the penalty for changing
accommodation units
  start_nodes = [node for node in grid if is_left_end(node)]
  end_condition = lambda node: is_right_end(node)
  list_of_penalty_func = [...]
  # Define the penalty function based on criteria
  def penalty_func(node1, node2):
    # Example: Penalty for changing from unit A to B
    return penalty_value if category(node1) != category(node2) else 0
  ## define other strategies
  ...
    list_of_penalty_func.append(penalty_func)
  list_best_path = bfs_with_dp_find_path(grid, start_nodes, end_condition,
list_of_penalty_func)
  if list_best_path is not [ ]:
    print(″The list of minimum cost paths from the left end to the right end of the
grid:″, list_best_path)
  else:
    print(″No path exists from the left end to the right end of the grid.″)
```

The algorithm starts by initializing the BFS with all nodes on the left end of the grid as the starting points, each with a cost of 0. The list strategies is initialized. The list of best paths is initially empty. The ‘min_cost’ dictionary keeps track of the minimum cost to reach each node, initialized to infinity for all nodes except the starting nodes.

In BFS with dynamic programming, the BFS explores each node level by level. For each node, it calculates the cost to reach its neighbors (sequential accommodation), including any penalties for changing units. If the new calculated cost is less than the current known cost for the neighbor, it updates the cost and enqueues the neighbor for further exploration.

The algorithm initially tries to find any path from the left end of the grid to the right end, ensuring there is a feasible way to traverse the grid without hitting a completely blocked column. This aspect is similar to solving a maze where the goal is to find a path from the start to the end. The strategies are continuously updated and filtered to make sure that only those within a certain penalty range of the minimum criterial value are kept. The list of best paths is continuously revised and updated with better paths. The algorithm relies on dynamic programming to keep track of the minimum criterial value (cost) at each step. Maintaining multiple strategies helps in finding the optimal strategies that minimize the overall cost while considering the penalty for changing accommodations.

The algorithm continues until the queue is exhausted and all available strategies are applied. It then checks the minimum cost among all nodes on the right end. It maintains the list of paths with lower cost. If no right end node was reached, it returns ‘None’, indicating no path exists.

This BFS with dynamic programming ensures that the list of minimum cost paths is found while considering multiple strategies for calculating penalties for changing accommodations, making it robust and efficient for various types of accommodations and penalty functions.

Possible functions that are relevant to implementations of various versions of the algorithms described herein are presented below.

### MazeMain.py

init: Initializes the MazeMain class with the given number of units and dates. It also initializes the grid and blocked arrays to store the availability and blocked status of the units, respectively. Additionally, it initializes the penalty and amenity correction arrays.

read_calendar_data: Reads the calendar data from a specified CSV file. It updates the grid and blocked arrays based on the data in the file. If a cell contains ‘b’, it marks that cell as blocked.

write_result_strategies: Writes the resulting strategies to a CSV and XLSX file. It creates a workbook and writes the grid data along with the strategies to the files. It uses different colors to fill the cells based on whether they are blocked or part of a strategy.

main block: This block is executed when the script is run directly. It initializes the MazeMain object with a specified number of rooms and dates. It reads the input data, sets the penalty and amenity correction values, and then solves the maze using the MazeSolver class. Finally, it writes the resulting strategies to output files.

### MazeSolver.py

init: Initializes the MazeSolver class with the given grid, blocked array, number of units, number of dates, penalty, and amenity correction values.

solve: Solves the maze by first calling solve_task_1 to find any path, and then solve_task_2 to find the optimal path based on the given criteria.

solve_task_1: Finds any path from the left end to the right end of the maze. It iterates through each column to find an unblocked cell and adds it to the rows_array. If it finds a column that is entirely blocked, it returns False. Otherwise, it marks the path on the accessibility map.

generate_accessibility_map: Generates an accessibility map based on the blocked array. It marks blocked cells with ‘x’ and unblocked cells with ‘.’

solve_task_2: Finds the optimal path from the left end to the right end of the maze. It starts by adding initial strategies for each unblocked unit in the first column. It then iterates through each day, adding branches for each possible room, and keeps track of the minimum criterial value. It filters out strategies that exceed the minimum criterial value plus the penalty and returns the optimal strategies.

### Strategy.py

init: Initializes the Strategy class with the given penalty value. It also initializes arrays to keep track of the rooms visited, accumulated prices, and costs, as well as the total price and criterial value.

lt: Defines the less-than operator for the Strategy class, comparing strategies based on their criterial values.

add_room: Adds a room to the strategy. It updates the price and criterial value based on the daily price and amenity correction. If the room changes from the previous day, it adds the penalty to the criterial value.

clone: Creates a copy of the current strategy, including its price, criterial value, rooms, costs, and accumulated prices.

print_strategy: Prints the details of the strategy, including the rooms visited and the corresponding costs and accumulated prices.

Preferred embodiments of this disclosure are described herein, including the best mode known to the inventors for carrying out the disclosure. It should be understood that the illustrated embodiments are exemplary only and should not be taken as limiting the scope of the disclosure.

The preceding description includes exemplary examples of the present disclosure. After describing example embodiments of the current disclosure, those knowledgeable in the art should be aware that the disclosures contained within are illustrative only, and that numerous other alternatives, adaptations, and changes may be made within the scope of the present disclosure. Simply stating or numbering the stages of a technique in a specific sequence does not impose any restrictions on the order of those steps. With the advantage of the teachings in the above descriptions, one knowledgeable in the art to which this disclosure belongs will have many changes and other embodiments of the disclosure spring to mind. Although particular terminology may be used in this document, they are solely intended in a generic and descriptive sense and not for the purpose of limiting. As a result, the current disclosure is not restricted to the precise embodiments depicted herein.

It should be appreciated that the techniques described herein can be applied to any suitable computer search algorithms and are not limited to a particular application, such as searching for accommodations matching a particular user request. Rather, the techniques described herein may be applied to any other suitable constraint satisfaction problem.

### EXAMPLES

Illustrative examples of the technologies disclosed herein are provided below. An embodiment of the technologies may include any one or more, and any combination of, the examples described below.

Example 1 includes a compute device comprising a processor; a memory communicatively coupled with the processor; and one or more non-transitory computer-readable media comprising a plurality of instructions stored thereon that, when executed by the processor, causes the processor to build a plan index, wherein the plan index comprises a plurality of documents, wherein, for individual documents of the plurality of documents, one or more document fields are defined, wherein to build the plan index comprises iterate through pairs of documents selected from the plurality of documents; determine that a value of a document field of the pairs of documents overlaps; and add an entry in the plan index based on the determination that the value of the document field of the pairs of documents overlaps, wherein the value of the document field of the entry corresponds to a combination of the document field of the pairs of documents; receive a query from a user, wherein the query comprises a search value for the document field; search the plan index based on the search value for the document field; and match the entry in the plan index to the query from the user.

Example 2 includes the subject matter of Example 1, and wherein to search the plan index comprises to build a range query based on the search value for the document field; and perform the range query.

Example 3 includes the subject matter of any of Examples 1 and 2, and wherein to search the plan index further comprises to determine that there are no matches for the range query; build, in response to the determination that there are no matches for the range query, a span query; and perform the span query.

Example 4 includes the subject matter of any of Examples 1-3, and wherein the plurality of documents represent a plurality of accommodation locations, wherein the query comprises a time range, wherein to build the plan index comprises to determine sets of one or more accommodation locations with overlapping availability.

Example 5 includes the subject matter of any of Examples 1-4, and wherein to match the entry the plan index comprises to determine two or more accommodation locations that have a combined availability that satisfies the time range.

Example 6 includes the subject matter of any of Examples 1-5, and wherein the plurality of instructions further cause the processor to receive a booking request from the user corresponding to the matched entry in the plan index; and create one reservation that includes the two or more accommodations.

Example 7 includes the subject matter of any of Examples 1-6, and wherein the query from the user comprises a check-in date, a check-out date, a location of interest, and criteria for amenities.

Example 8 includes the subject matter of any of Examples 1-7, and wherein the query from the user comprises an amenity criterial value representing a penalty for not having a corresponding amenity.

Example 9 includes a compute device comprising a processor; a memory communicatively coupled with the processor; and one or more non-transitory computer-readable media comprising a plurality of instructions stored thereon that, when executed by the processor, causes the processor to generate, by a compute device, a training corpus for fine-tuning a large-language model (LLM), wherein the training corpus comprises a plurality of textual parameters and a plurality of numerical parameters for each of a plurality of objects; fine-tune the LLM based on the training corpus; receive a query from a user, wherein the query comprises a one or more required constraints and one or more preferences regarding possible matches the plurality of objects, wherein the query is formed in natural language; transform, with use of the LLM, the query from the user into a formal constraint satisfaction problem (CSP); solve the CSP to determine one or more objects of the plurality of objects that satisfy the CSP; and provide the one or more objects to the user.

Example 10 includes the subject matter of Example 9, and wherein to solve the CSP comprises to solve the CSP with use of the LLM.

Example 11 includes the subject matter of any of Examples 9 and 10, and wherein the plurality of objects represent a plurality of accommodation locations, wherein the query comprises a time range, wherein to solve the CSP comprises to determine sets of one or more accommodation locations with overlapping availability.

Example 12 includes the subject matter of any of Examples 9-11, and wherein to solve the CSP comprises to determine two or more accommodation locations that have a combined availability that satisfies the time range, wherein to provide the one or more objects to the user comprises to provide the two or more accommodation locations that have the combined availability that satisfies the time range as expressed by the CSP.

Example 13 includes the subject matter of any of Examples 9-12, and further including receive a booking request from the user corresponding to the two or more accommodation locations that have the combined availability that satisfies the time range; and create one reservation that includes the two or more accommodations.

Example 14 includes the subject matter of any of Examples 9-13, and wherein the query from the user comprises a check-in date, a check-out date, a location of interest, and criteria for amenities.

Example 15 includes the subject matter of any of Examples 9-14, and wherein the query from the user comprises an amenity criterial value representing a penalty for not having a corresponding amenity.

Example 16 includes a compute device comprising a processor; a memory communicatively coupled with the processor; and one or more non-transitory computer-readable media comprising a plurality of instructions stored thereon that, when executed by the processor, causes the processor to receive, by a compute device, a query from a user, wherein the query comprises a search value, wherein the search value comprises a time range; initialize a breadth first search on a grid, wherein the grid represents a plurality of documents; and perform the breadth first search to satisfy the query. In some embodiments, performing the breadth first search may comprise applying extended dynamic programming by keeping track of a minimum cost at each of a plurality of nodes of the grid and retaining multiple potential paths associated with varying costs at each of the plurality of nodes and using a penalty function for changing node categories.

Example 17 includes the subject matter of Example 16, and wherein the plurality of documents represent a plurality of accommodation locations, wherein the query comprises a time range, wherein to perform the breadth first search comprises to determine sets of one or more accommodation locations with overlapping availability.

Example 18 includes the subject matter of any of Examples 16 and 17, and wherein to perform the breadth first search comprises to determine two or more accommodation locations that have a combined availability that satisfies the time range.

Example 19 includes the subject matter of any of Examples 16-18, and wherein the plurality of instructions further cause the compute device to receive a booking request from the user corresponding to the two or more accommodation locations that have a combined availability that satisfies the time range; and create one reservation that includes the two or more accommodations.

Example 20 includes the subject matter of any of Examples 16-19, and wherein the query from the user comprises a check-in date, a check-out date, a location of interest, and criteria for amenities.

Example 21 includes the subject matter of any of Examples 16-20, and wherein the query from the user comprises an amenity criterial value representing a penalty for not having a corresponding amenity.

Example 22 includes a method comprising building, by a compute device, a plan index, wherein the plan index comprises a plurality of documents, wherein, for individual documents of the plurality of documents, one or more document fields are defined, wherein building the plan index comprises iterating through pairs of documents selected from the plurality of documents; determining that a value of a document field of the pairs of documents overlaps; and adding an entry in the plan index based on the determination that the value of the document field of the pairs of documents overlaps, wherein the value of the document field of the entry corresponds to a combination of the document field of the pairs of documents; receiving, by the compute device, a query from a user, wherein the query comprises a search value for the document field; searching, by the compute device, the plan index based on the search value for the document field; and matching, by the compute device, the entry in the plan index to the query from the user.

Example 23 includes the subject matter of Example 22, and wherein searching the plan index comprises building, by the compute device, a range query based on the search value for the document field; and performing, by the compute device, the range query.

Example 24 includes the subject matter of any of Examples 22 and 23, and wherein searching the plan index further comprises determining, by the compute device, that there are no matches for the range query; building, by the compute device and in response to the determination that there are no matches for the range query, a span query; and performing, by the compute device, the span query.

Example 25 includes the subject matter of any of Examples 22-24, and wherein the plurality of documents represent a plurality of accommodation locations, wherein the query comprises a time range, wherein building the plan index comprises determining sets of one or more accommodation locations with overlapping availability.

Example 26 includes the subject matter of any of Examples 22-25, and wherein matching the entry the plan index comprises determining two or more accommodation locations that have a combined availability that satisfies the time range.

Example 27 includes the subject matter of any of Examples 22-26, and further including receiving, by the compute device, a booking request from the user corresponding to the matched entry in the plan index; and creating, by the compute device, one reservation that includes the two or more accommodations.

Example 28 includes the subject matter of any of Examples 22-27, and wherein the query from the user comprises a check-in date, a check-out date, a location of interest, and criteria for amenities.

Example 29 includes the subject matter of any of Examples 22-28, and wherein the query from the user comprises an amenity criterial value representing a penalty for not having a corresponding amenity.

Example 30 includes a method comprising generating, by a compute device, a training corpus for fine-tuning a large-language model (LLM), wherein the training corpus comprises a plurality of textual parameters and a plurality of numerical parameters for each of a plurality of objects; fine-tuning, by the compute device, the LLM based on the training corpus; receiving, by the compute device, a query from a user, wherein the query comprises a one or more required constraints and one or more preferences regarding possible matches the plurality of objects, wherein the query is formed in natural language; transforming, by the compute device and with use of the LLM, the query from the user into a formal constraint satisfaction problem (CSP); solving, by the compute device, the CSP to determine one or more objects of the plurality of objects that satisfy the CSP; and providing, by the compute device, the one or more objects to the user.

Example 31 includes the subject matter of Example 30, and wherein solving the CSP comprises solving the CSP with use of the LLM.

Example 32 includes the subject matter of any of Examples 30 and 31, and wherein the plurality of objects represent a plurality of accommodation locations, wherein the query comprises a time range, wherein solving the CSP comprises determining sets of one or more accommodation locations with overlapping availability.

Example 33 includes the subject matter of any of Examples 30-32, and wherein solving the CSP comprises determining two or more accommodation locations that have a combined availability that satisfies the time range, wherein providing the one or more objects to the user comprises providing the two or more accommodation locations that have the combined availability that satisfies the time range as expressed by the CSP.

Example 34 includes the subject matter of any of Examples 30-33, and further including receiving, by the compute device, a booking request from the user corresponding to the two or more accommodation locations that have the combined availability that satisfies the time range; and creating, by the compute device, one reservation that includes the two or more accommodations.

Example 35 includes the subject matter of any of Examples 30-34, and wherein the query from the user comprises a check-in date, a check-out date, a location of interest, and criteria for amenities.

Example 36 includes the subject matter of any of Examples 30-35, and wherein the query from the user comprises an amenity criterial value representing a penalty for not having a corresponding amenity.

Example 37 includes a method comprising receiving, by a compute device, a query from a user, wherein the query comprises a search value, wherein the search value comprises a time range; initializing, by the compute device, a breadth first search on a grid, wherein the grid represents a plurality of documents; and performing, by the compute device, the breadth first search to satisfy the query.

Example 38 includes the subject matter of Example 37, and wherein the plurality of documents represent a plurality of accommodation locations, wherein the query comprises a time range, wherein performing the breadth first search comprises determining sets of one or more accommodation locations with overlapping availability, wherein one or more criteria of the query are automatically updated based on a current state of search results of the grid.

Example 39 includes the subject matter of any of Examples 37 and 38, and wherein performing the breadth first search comprises determining two or more accommodation locations that have a combined availability that satisfies the time range.

Example 40 includes the subject matter of any of Examples 37-39, and further including receiving, by the compute device, a booking request from the user corresponding to the two or more accommodation locations that have a combined availability that satisfies the time range; and creating, by the compute device, one reservation that includes the two or more accommodations.

Example 41 includes the subject matter of any of Examples 37-40, and wherein the query from the user comprises a check-in date, a check-out date, a location of interest, and criteria for amenities.

Example 42 includes the subject matter of any of Examples 37-41, and wherein the query from the user comprises an amenity criterial value representing a penalty for not having a corresponding amenity.

Example 43 includes a compute device comprising means for building a plan index, wherein the plan index comprises a plurality of documents, wherein, for individual documents of the plurality of documents, one or more document fields are defined, wherein the means for building the plan index comprises means for iterating through pairs of documents selected from the plurality of documents; means for determining that a value of a document field of the pairs of documents overlaps; and means for adding an entry in the plan index based on the determination that the value of the document field of the pairs of documents overlaps, wherein the value of the document field of the entry corresponds to a combination of the document field of the pairs of documents; means for receiving a query from a user, wherein the query comprises a search value for the document field; means for searching the plan index based on the search value for the document field; and means for matching the entry in the plan index to the query from the user.

Example 44 includes the subject matter of Example 43, and wherein the means for searching the plan index comprises means for building a range query based on the search value for the document field; and means for performing the range query.

Example 45 includes the subject matter of any of Examples 43 and 44, and wherein the means for searching the plan index further comprises means for determining that there are no matches for the range query; means for building, in response to the determination that there are no matches for the range query, a span query; and means for performing the span query.

Example 46 includes the subject matter of any of Examples 43-45, and wherein the plurality of documents represent a plurality of accommodation locations, wherein the query comprises a time range, wherein the means for building the plan index comprises means for determining sets of one or more accommodation locations with overlapping availability.

Example 47 includes the subject matter of any of Examples 43-46, and wherein the means for matching the entry the plan index comprises means for determining two or more accommodation locations that have a combined availability that satisfies the time range.

Example 48 includes the subject matter of any of Examples 43-47, and further including means for receiving a booking request from the user corresponding to the matched entry in the plan index; and means for creating one reservation that includes the two or more accommodations.

Example 49 includes the subject matter of any of Examples 43-48, and wherein the query from the user comprises a check-in date, a check-out date, a location of interest, and criteria for amenities.

Example 50 includes the subject matter of any of Examples 43-49, and wherein the query from the user comprises an amenity criterial value representing a penalty for not having a corresponding amenity.

Example 51 includes a compute device comprising means for generating a training corpus for fine-tuning a large-language model (LLM), wherein the training corpus comprises a plurality of textual parameters and a plurality of numerical parameters for each of a plurality of objects; means for fine-tuning the LLM based on the training corpus; means for receiving a query from a user, wherein the query comprises a one or more required constraints and one or more preferences regarding possible matches the plurality of objects, wherein the query is formed in natural language; means for transforming, with use of the LLM, the query from the user into a formal constraint satisfaction problem (CSP); means for solving the CSP to determine one or more objects of the plurality of objects that satisfy the CSP; and means for providing the one or more objects to the user.

Example 52 includes the subject matter of Example 51, and wherein the means for solving the CSP comprises means for solving the CSP with use of the LLM.

Example 53 includes the subject matter of any of Examples 51 and 52, and wherein the plurality of objects represent a plurality of accommodation locations, wherein the query comprises a time range, wherein the means for solving the CSP comprises means for determining sets of one or more accommodation locations with overlapping availability.

Example 54 includes the subject matter of any of Examples 51-53, and wherein the means for solving the CSP comprises means for determining two or more accommodation locations that have a combined availability that satisfies the time range, wherein the means for providing the one or more objects to the user comprises means for providing the two or more accommodation locations that have the combined availability that satisfies the time range as expressed by the CSP.

Example 55 includes the subject matter of any of Examples 51-54, and further including means for receiving a booking request from the user corresponding to the two or more accommodation locations that have the combined availability that satisfies the time range; and means for creating one reservation that includes the two or more accommodations.

Example 56 includes the subject matter of any of Examples 51-55, and wherein the query from the user comprises a check-in date, a check-out date, a location of interest, and criteria for amenities.

Example 57 includes the subject matter of any of Examples 51-56, and wherein the query from the user comprises an amenity criterial value representing a penalty for not having a corresponding amenity.

Example 58 includes a compute device comprising means for receiving a query from a user, wherein the query comprises a search value, wherein the search value comprises a time range; means for initializing a breadth first search on a grid, wherein the grid represents a plurality of documents; and means for performing the breadth first search to satisfy the query.

Example 59 includes the subject matter of Example 58, and wherein the plurality of documents represent a plurality of accommodation locations, wherein the query comprises a time range, wherein the means for performing the breadth first search comprises means for determining sets of one or more accommodation locations with overlapping availability, wherein one or more criteria of the query are automatically updated based on a current state of search results of the grid.

Example 60 includes the subject matter of any of Examples 58 and 59, and wherein the means for performing the breadth first search comprises means for determining two or more accommodation locations that have a combined availability that satisfies the time range.

Example 61 includes the subject matter of any of Examples 58-60, and further including means for receiving a booking request from the user corresponding to the two or more accommodation locations that have a combined availability that satisfies the time range; and means for creating one reservation that includes the two or more accommodations.

Example 62 includes the subject matter of any of Examples 58-61, and wherein the query from the user comprises a check-in date, a check-out date, a location of interest, and criteria for amenities.

Example 63 includes the subject matter of any of Examples 58-62, and wherein the query from the user comprises an amenity criterial value representing a penalty for not having a corresponding amenity.

Example 64 includes one or more non-transitory computer-readable media comprising a plurality of instructions stored thereon that, when executed, causes a compute device to build a plan index, wherein the plan index comprises a plurality of documents, wherein, for individual documents of the plurality of documents, one or more document fields are defined, wherein to build the plan index comprises iterate through pairs of documents selected from the plurality of documents; determine that a value of a document field of the pairs of documents overlaps; and add an entry in the plan index based on the determination that the value of the document field of the pairs of documents overlaps, wherein the value of the document field of the entry corresponds to a combination of the document field of the pairs of documents; receive a query from a user, wherein the query comprises a search value for the document field; search the plan index based on the search value for the document field; and match the entry in the plan index to the query from the user.

Example 65 includes the subject matter of Example 64, and wherein to search the plan index comprises to build a range query based on the search value for the document field; and perform the range query.

Example 66 includes the subject matter of any of Examples 64 and 65, and wherein to search the plan index further comprises to determine that there are no matches for the range query; build, in response to the determination that there are no matches for the range query, a span query; and perform the span query.

Example 67 includes the subject matter of any of Examples 64-66, and wherein the plurality of documents represent a plurality of accommodation locations, wherein the query comprises a time range, wherein to build the plan index comprises to determine sets of one or more accommodation locations with overlapping availability.

Example 68 includes the subject matter of any of Examples 64-67, and wherein to match the entry the plan index comprises to determine two or more accommodation locations that have a combined availability that satisfies the time range.

Example 69 includes the subject matter of any of Examples 64-68, and wherein the plurality of instructions further cause the processor to receive a booking request from the user corresponding to the matched entry in the plan index; and create one reservation that includes the two or more accommodations.

Example 70 includes the subject matter of any of Examples 64-69, and wherein the query from the user comprises a check-in date, a check-out date, a location of interest, and criteria for amenities.

Example 71 includes the subject matter of any of Examples 64-70, and wherein the query from the user comprises an amenity criterial value representing a penalty for not having a corresponding amenity.

Example 72 includes one or more non-transitory computer-readable media comprising a plurality of instructions stored thereon that, when executed, causes a compute device to generate a training corpus for fine-tuning a large-language model (LLM), wherein the training corpus comprises a plurality of textual parameters and a plurality of numerical parameters for each of a plurality of objects; fine-tune the LLM based on the training corpus; receive a query from a user, wherein the query comprises a one or more required constraints and one or more preferences regarding possible matches the plurality of objects, wherein the query is formed in natural language; transform, with use of the LLM, the query from the user into a formal constraint satisfaction problem (CSP); solve the CSP to determine one or more objects of the plurality of objects that satisfy the CSP; and provide the one or more objects to the user.

Example 73 includes the subject matter of Example 72, and wherein to solve the CSP comprises to solve the CSP with use of the LLM.

Example 74 includes the subject matter of any of Examples 72 and 73, and wherein the plurality of objects represent a plurality of accommodation locations, wherein the query comprises a time range, wherein to solve the CSP comprises to determine sets of one or more accommodation locations with overlapping availability.

Example 75 includes the subject matter of any of Examples 72-74, and wherein to solve the CSP comprises to determine two or more accommodation locations that have a combined availability that satisfies the time range, wherein to provide the one or more objects to the user comprises to provide the two or more accommodation locations that have the combined availability that satisfies the time range as expressed by the CSP.

Example 76 includes the subject matter of any of Examples 72-75, and further including receive a booking request from the user corresponding to the two or more accommodation locations that have the combined availability that satisfies the time range; and create one reservation that includes the two or more accommodations.

Example 77 includes the subject matter of any of Examples 72-76, and wherein the query from the user comprises a check-in date, a check-out date, a location of interest, and criteria for amenities.

Example 78 includes the subject matter of any of Examples 72-77, and wherein the query from the user comprises an amenity criterial value representing a penalty for not having a corresponding amenity.

Example 79 includes one or more non-transitory computer-readable media comprising a plurality of instructions stored thereon that, when executed, causes a compute device to receive a query from a user, wherein the query comprises a search value, wherein the search value comprises a time range; initialize a breadth first search on a grid, wherein the grid represents a plurality of documents; and perform the breadth first search to satisfy the query.

Example 80 includes the subject matter of Example 79, and wherein the plurality of documents represent a plurality of accommodation locations, wherein the query comprises a time range, wherein to perform the breadth first search comprises to determine sets of one or more accommodation locations with overlapping availability, wherein one or more criteria of the query are automatically updated based on a current state of search results of the grid.

Example 81 includes the subject matter of any of Examples 79 and 80, and wherein to perform the breadth first search comprises to determine two or more accommodation locations that have a combined availability that satisfies the time range.

Example 82 includes the subject matter of any of Examples 79-81, and wherein the plurality of instructions further cause the compute device to receive a booking request from the user corresponding to the two or more accommodation locations that have a combined availability that satisfies the time range; and create one reservation that includes the two or more accommodations.

Example 83 includes the subject matter of any of Examples 79-82, and wherein the query from the user comprises a check-in date, a check-out date, a location of interest, and criteria for amenities.

Example 84 includes the subject matter of any of Examples 79-83, and wherein the query from the user comprises an amenity criterial value representing a penalty for not having a corresponding amenity.

1. An apparatus comprising:
a voltage-controlled oscillator comprising:
a first inductor;
a second inductor, wherein the first inductor and second inductor have a mutual inductance; and
a set of switches to control a phase between a current in the first inductor and a current in the second inductor.

2. The apparatus of claim 1, further comprising:
a first pair of wires connected to the first inductor, the first pair of wires comprising a first wire and a second wire;
a second pair of wires connected to the second inductor, the second pair of wires comprising a third wire and a fourth wire; and
a second set of switches to select between a first configuration and a second configuration, wherein, in the first configuration, the first wire is shorted to the third wire and the second wire is shorted to the fourth wire, wherein, in the second configuration, the first wire is shorted to the fourth wire and the second wire is shorted to the third wire.

3. The apparatus of claim 2, further comprising control circuitry to control the set of switches and the second set of switches.

4. The apparatus of claim 2, further comprising a first pair of capacitively-coupled alternating current (AC) buffers connected to the first pair of wires and a second pair of capacitively-coupled AC buffers connected to the second pair of wires, further comprising a multiplexer to selectably combine an output of the first AC buffer and an output of the second AC buffer in different configurations.

5. The apparatus of claim 1, wherein the first inductor and the second inductor are defined on different layers on a substrate.

6. The apparatus of claim 5, wherein, from a top-down perspective on the substrate, the first inductor at least partially overlaps with the second inductor.

7. The apparatus of claim 5, wherein, from a top-down perspective on the substrate, the first inductor does not overlap with the second inductor.

8. The apparatus of claim 1, further comprising a first plurality of variable capacitors coupled to the first inductor and a second plurality of variable capacitors coupled to the second inductor, where the first inductor and the first plurality of variable capacitors compose a first oscillator, wherein the second inductor and the second plurality of variable capacitors compose a second oscillator.

9. The apparatus of claim 8, wherein, in a first mode of the set of switches, the phase between a current in the first oscillator and a current in the second oscillator is zero degrees, wherein, in the first mode, a frequency range of the first oscillator has a first minimum and a first maximum,
wherein, in a second mode of the set of switches, the phase between a current in the first oscillator and a current in the second oscillator is 180 degrees, wherein, in the second mode, a frequency range of the first oscillator has a second minimum and a second maximum.

10. The apparatus of claim 9, wherein, in a third mode of the set of switches, the second oscillator is disabled, wherein, in the third mode, a frequency range of the first oscillator has a third minimum and a third maximum.

11. The apparatus of claim 10, wherein the first inductor has a first inductance, wherein the second inductor has a second inductance different from the first inductance, wherein, in a fourth mode of the set of switches, the first oscillator is disabled, wherein, in the fourth mode, a frequency range of the second oscillator has a fourth minimum and a fourth maximum.

12. The apparatus of claim 1, further comprising a third inductor, wherein the set of switches is able to selectively enable or disable the second inductor and the third inductor, wherein the set of switches is to control a phase between a current in the first inductor and a current in the third inductor when the third inductor is enabled and the second inductor is disabled, wherein there is a first center-to-center spacing between the first inductor and the second inductor, wherein there is a second center-to-center spacing between the first inductor and the third inductor, wherein there is a third center-to-center spacing between the second inductor and the third inductor, wherein the first center-to-center spacing, the second center-to-center spacing, and the third center-to-center spacing are different from each other by at least 10%.

13. A voltage-controlled oscillator (VCO) comprising:
a first inductor;
a second inductor, wherein the first inductor and the second inductor are electromagnetically coupled and configured to provide a mutual inductance; and
a set of switches configured to control a relative phase between a signal in the first inductor and a signal in the second inductor, wherein the relative phase determines the mutual inductance and an effective inductance and enables operation in at least two distinct modes.

14. The voltage-controlled oscillator of claim 13, further comprising:
a first pair of terminals connected to the first inductor, the first pair of terminals comprising a first terminal and a second terminal;
a second pair of terminals connected to the second inductor, the second pair of terminals comprising a third terminal and a fourth terminal; and
a second set of switches configured to selectively connect the first terminal to the third terminal and the second terminal to the fourth terminal in a first configuration, or the first terminal to the fourth terminal and the second terminal to the third terminal in a second configuration.

15. The voltage-controlled oscillator of claim 14, further comprising control circuitry configured to operate the set of switches and the second set of switches to select between the first configuration and the second configuration.

16. The voltage-controlled oscillator of claim 14, further comprising:
a first pair of capacitively-coupled alternating current (AC) buffers connected to the first pair of terminals; and
a second pair of capacitively-coupled AC buffers connected to the second pair of terminals, wherein the pairs of capacitively-coupled AC buffers are configured through two sets of switches to combine outputs from the first inductor and the second inductor.

17. The voltage-controlled oscillator of claim 13, wherein the first inductor and the second inductor are disposed on different layers of a substrate.

18. The voltage-controlled oscillator of claim 17, wherein the first inductor and the second inductor are configured such that, from a top-down perspective on the substrate, the first inductor at least partially overlaps with the second inductor.

19. A method of operating a voltage-controlled oscillator (VCO), the method comprising:
configuring a set of switches to control a relative phase between a current in a first inductor and a current in a second inductor, the first and second inductors being electromagnetically coupled to provide a mutual inductance; and
selecting a mode of operation by setting the relative phase to a first value or a second value, wherein the first value corresponds to a phase difference of approximately zero degrees and the second value corresponds to a phase difference of approximately 180 degrees.

20. The method of claim 19, further comprising:
connecting a first pair of terminals of the first inductor and a second pair of terminals of the second inductor to a switching network;
shorting a first terminal of the first inductor to a first terminal of the second inductor and a second terminal of the first inductor to a second terminal of the second inductor in order to place the VCO in a first configuration; and
shorting the first terminal of the first inductor to the second terminal of the second inductor and the second terminal of the first inductor to the first terminal of the second inductor in order to place the VCO in a second configuration.
